(19) United States
(12) Patent Application Publication
(10) Pub. No.: US 2026/0196524 A1
(43) Pub. Date: Jul. 9, 2026

(54) A METHOD FOR CONTROLLING A WORK FUNCTION OF AT LEAST ONE SURFACE, ELECTRODE, ELECTROCHEMICAL CELL ENERGY STORAGE DEVICE, PHOTOVOLTAIC CELL AND ELECTRICAL COMPONENT THEREOF

(71) Applicants: CHIRAL LTD, Rosh Ha 'Ayin (IL); Yissum Research Development Company, Givat Ram, Jerusalem (IL); YEDA RESEARCH AND DEVELOPMENT CO. LTD., Rehovot (IL)

(72) Inventors: Ron NAAMAN, Yarkona (IL); Yosef PALTIEL, Rehovot (IL); Shira YOCHELIS, Ness Ziona (IL); Nir YURAN, Tel Aviv (IL); Yutao SANG, Shanghai (CN); Uri WEINHEBER, Matan (IL); Nir MAROM, Tzur Moshe (IL)

(21) Appl. No.: 18/868,873

(22) PCT Filed: May 24, 2023
(86) PCT No.: PCT/IL2023/050544

§ 371 Date: Nov. 25, 2024

Related U.S. Application Data
(60) Provisional application No. 63/346,094, filed on May 26, 2022.
(60) Provisional application No. 63/390,300, filed on Jul. 19, 2022.
(60) Provisional application No. 63/403,761, filed on Sep. 4, 2022.

(51) Int. Cl. H01M 4/90; H01M 8/083; H01M 8/16; H10K 30/50

(52) U.S. Cl. CPC H01M 4/9008; H01M 8/083; H01M 8/16; H10K 30/50

(57) ABSTRACT

Some embodiments relates inter alia to a method for controlling a work function of at least one surface comprising: measuring a first work function of a first surface; depositing a chiral system on the first surface to cause change in the first work function; applying a potential difference between the first surface and a second surface, such that to create a charge transfer between the first and second surfaces; measuring a second work function of the first surface carrying the chiral system; wherein the second work function is lower than the first work function. The interaction between the chiral system and the first surface is configured for causing charge rearrangement, spin polarization of the surface, and spin polarization of electrons being injected from or to the first surface, thereby modifying the work function of the first surface. The present disclosure also relates to electrodes, electrochemical cells, energy storage devices, photovoltaic cells, and electrical components, thereof.

### CROSS-REFERENCE TO RELATED APPLICATIONS

This application is a national phase filing under 35 C.F.R. § 371 of and claims priority to PCT Patent Application No. PCT/IL2023/050544, filed on May 24, 2023, which claims the priority benefit under 35 U.S.C. § 119 of U.S. Provisional Patent Application No. 63/403,761, filed on Sep. 4, 2022, U.S. Provisional Patent Application No. 63/390,300, filed on Jul. 19, 2022, and U.S. Provisional Patent Application No. 63/346,094, filed on May 26, 2022, the content of which is hereby incorporated in its entirety by reference.

### TECHNOLOGICAL FIELD

The present disclosure generally relates to electrodes, electrochemical cells, energy storage devices, photovoltaic cells and electrical components. Particularly, but not exclusively, the present disclosure relates also to a method for controlling a work function of at least one surface.

### BACKGROUND ART

References considered to be relevant as background to the presently disclosed subject matter are listed below:
1. Duan, J. et al. Building Safe Lithium-Ion Batteries for Electric Vehicles: A Review. Electrochemical Energy Reviews vol. 3 Preprint at https://doi.org/10.1007/s41918-019-00060-4 (2020).
2. Goodenough, J. B. Energy storage materials: A perspective. Energy Storage Materials vol. 1 158-161 Preprint at https://doi.org/10.1016/j.ensm.2015.07.001 (2015).
3. Schipper, F. et al. Review-Recent Advances and Remaining Challenges for Lithium Ion Battery Cathodes. J Electrochem Soc 164, A6220-A6228 (2017).
4. Sun, Y. K. et al. High-energy cathode material for long-life and safe lithium batteries. Nat Mater 8, 320-324 (2009).
5. Sun, Y., Liu, N. & Cui, Y. Promises and challenges of nanomaterials for lithium-based rechargeable batteries. Nature Energy vol. 1 Preprint at https://doi.org/10.1038/nenergy.2016.71 (2016).
6. Lim, B. B. et al. Advanced Concentration Gradient Cathode Material with Two-Slope for High-Energy and Safe Lithium Batteries. Adv Funct Mater 25, 4673-4680 (2015).
7. Manthiram, A., Song, B. & Li, W. A perspective on nickel-rich layered oxide cathodes for lithium-ion batteries. Energy Storage Materials vol. 6 125-139 Preprint at https://doi.org/10.1016/j.ensm.2016.10.007 (2017).
8. Manthiram, A., Knight, J. C., Myung, S. T., Oh, S. M. & Sun, Y. K. Nickel-Rich and Lithium-Rich Layered Oxide Cathodes: Progress and Perspectives. Adv Energy Mater 6, (2016).
9. Liu, W. et al. Nickel-Rich Layered Lithium Transition-Metal Oxide for High-Energy Lithium-Ion Batteries. Angewandte Chemie 127, 4518-4536 (2015).
10. Xia, Y., Zheng, J., Wang, C. & Gu, M. Designing principle for Ni-rich cathode materials with high energy density for practical applications. Nano Energy vol. 49 434-452 Preprint at https://doi.org/10.1016/j.nanoen.2018.04.062 (2018).
11. Weigel, T. et al. Structural and Electrochemical Aspects of LiNi 0.8 Co 0.1 Mn 0.1 O 2 Cathode Materials Doped by Various Cations. ACS Energy Lett 4, 508-516 (2019).
12. Li, T. et al. Degradation Mechanisms and Mitigation Strategies of Nickel-Rich NMC-Based Lithium-Ion Batteries. Electrochemical Energy Reviews vol. 3 43-80 Preprint at https://doi.org/10.1007/s41918-019-00053-3 (2020).
13. Deng, S. et al. Manipulation of an ionic and electronic conductive interface for highly-stable high-voltage cathodes. Nano Energy 65, (2019).
14. Zhang, J. et al. Suppressing the Structure Deterioration of Ni-Rich LiNi0.8Co0.1Mn0.1O2 through Atom-Scale Interfacial Integration of Self-Forming Hierarchical Spinel Layer with Ni Gradient Concentration. ACS Appl Mater Interfaces 9, 29794-29803 (2017).
15. Wang, H. et al. Enhanced interfacial reaction interface stability of Ni-rich cathode materials by fabricating dual-modified layer coating for lithium-ion batteries. Electrochim Acta 366, (2021).
16. Wang, K. X., Li, X. H. & Chen, J. S. Surface and interface engineering of electrode materials for lithium-ion batteries. Advanced Materials 27, 527-545 (2015).
17. Kalluri, S. et al. Feasibility of Cathode Surface Coating Technology for High-Energy Lithium-ion and Beyond-Lithium-ion Batteries. Advanced Materials 29, (2017).
18. Lin, F. et al. Surface reconstruction and chemical evolution of stoichiometric layered cathode materials for lithium-ion batteries. Nat Commun 5, 3529 (2014).
19. Xu, G. L. et al. Building ultraconformal protective layers on both secondary and primary particles of layered lithium transition metal oxide cathodes. Nat Energy 4, 484-494 (2019).
20. Cheng, X. et al. Realizing superior cycling stability of Ni-Rich layered cathode by combination of grain boundary engineering and surface coating. Nano Energy 62, 30-37 (2019).
21. Meng, X., Yang, X. Q. & Sun, X. Emerging applications of atomic layer deposition for lithium-ion battery studies. Advanced Materials vol. 24 3589-3615 Preprint at https://doi.org/10.1002/adma.201200397 (2012).
22. Assaud, L., Pitzschel, K., Hanbücken, M. & Santinacci, L. Highly-Conformal TiN Thin Films Grown by Thermal and Plasma-Enhanced Atomic Layer Deposition. ECS Journal of Solid State Science and Technology 3, P 253-P 258 (2014).
23. Yang, H. et al. Simultaneously Dual Modification of Ni-Rich Layered Oxide Cathode for High-Energy Lithium-Ion Batteries. Adv Funct Mater 29, (2019).
24. Kim, H., Kim, M. G., Jeong, H. Y., Nam, H. & Cho, J. A new coating method for alleviating surface degradation of LiNi0.6Co0.2Mn0.2O2 cathode material: Nanoscale surface treatment of primary particles. Nano Lett 15, 2111-2119 (2015).
25. Sun, H. H. et al. Transition metal-doped Ni-rich layered cathode materials for durable Li-ion batteries. Nat Commun 12, (2021).
26. Tian, C., Lin, F. & Doeff, M. M. Electrochemical Characteristics of Layered Transition Metal Oxide Cathode Materials for Lithium Ion Batteries: Surface, Bulk Behavior, and Thermal Properties. Acc Chem Res 51, 89-96 (2018).
27. Kim, J. et al. Self-Induced Concentration Gradient in Nickel-Rich Cathodes by Sacrificial Polymeric Bead Clusters for High-Energy Lithium-Ion Batteries. Adv Energy Mater 7, (2017).
28. Li, S. et al. An effective approach to improve the electrochemical performance of LiNi0.6Co0.2Mn0.2O2 cathode by an MOF-derived coating. J Mater Chem A Mater 4, 5823-5827 (2016).
29. Sun, D., Sun, F., Deng, X. & Li, Z. Mixed-Metal Strategy on Metal-Organic Frameworks (MOFs) for Functionalities Expansion: Co Substitution Induces Aerobic Oxidation of Cyclohexene over Inactive Ni-MOF-74. Inorg Chem 54, 8639-8643 (2015).
30. G. T. Babcock, How oxygen is activated and reduced in respiration. Proc. Natl. Acad. Sci. U.S.A 96, 12971-12973 (1999).
31. S. M. M. Ehteshami, S. H. Chan, The role of hydrogen and fuel cells to store renewable energy in the future energy network-potentials and challenges. Energy Policy 73, 103-109 (2014).
32. A. Bauen, F. Foradini, D. Hart, “Fuel cell-based renewable energy supply: sustainable energy for isolated and island communities” in New and Renewable Technologies for Sustainable Development, N. H. Afgan, M. da Graça Carvalho, Eds. (Springer, Boston, 2002), pp. 421-428.
33. S. Ferguson-Miller, G. T. Babcock, Heme/copper terminal oxidases. Chem. Rev. 96, 2889-2908 (1996).
34. P. J. Silva, Refining the reaction mechanism of O2 towards its co-substrate in cofactor-free dioxygenases. PeerJ 4, e2805 (2016).
35. L. Gabison, C. Chopard, N. Colloc'h, F. Peyrot, B. Castro, M. E. Hajji, M. Altarsha, G. Monard, M. Chiadmi, T. Prangé, X-ray, ESR, and quantum mechanics studies unravel a spin well in the cofactor-less urate oxidase. Proteins 79, 1964-1976 (2011).
36. A. Kulkarni, S. Siahrostami, A. Patel, J. K. Nørskov, Understanding catalytic activity trends in the oxygen reduction reaction. Chem. Rev. 118, 2302-2312 (2018).
37. J. K. Nørskov, J. Rossmeisl, A. Logadottir, L. Lindqvist, Origin of the overpotential for oxygen reduction at a fuel-cell cathode. J. Phys. Chem. B 108, 17886-17892 (2004).
38. Z. W. Seh, J. Kibsgaard, C. F. Dickens, I. Chorkendorff, J. K. Nørskov, T. F. Jaramillo, Combining theory and experiment in electrocatalysis: Insights into materials design. Science 355, eaad4998 (2017).
39. Supriya Ghosh, Suryakant Mishra, Eytan Avigad, Brian P. Bloom, L. T. Baczewski, Shira Yochelis, Yossi Paltiel, Ron Naaman, David H. Waldeck, Effect of Chiral Molecules on the Electron's Spin Wavefunction at Interfaces, J. Phys. Chem. Lett. 11, 1550-1557 (2020).
40. Naaman, R. & Waldeck, D. H. Chiral-induced spin selectivity effect. Journal of Physical Chemistry Letters 3, 2178-2187 (2012).
41. Naaman, R. & Waldeck, D. H. Spintronics and chirality: Spin selectivity in electron transport through chiral molecules. Annual Review of Physical Chemistry vol. 66 263-281 Preprint at https://doi.org/10.1146/annurev-physchem-040214-121554 (2015).
42. Naaman, R., Paltiel, Y. & Waldeck, D. H. Chiral molecules and the electron spin. Nature Reviews Chemistry vol. 3 250-260 Preprint at https://doi.org/10.1038/s41570-019-0087-1 (2019).
43. Evers, F. et al. Theory of Chirality Induced Spin Selectivity: Progress and Challenges. Advanced Materials vol. 34 Preprint at https://doi.org/10.1002/adma.202106629 (2022).
44. Kumar, A. et al. Chirality-induced spin polarization places symmetry constraints on biomolecular interactions. Proc Natl Acad Sci USA 114, 2474-2478 (2017).
45. Michaeli, K., Kantor-Uriel, N., Naaman, R. & Waldeck, D. H. The electron's spin and molecular chirality-how are they related and how do they affect life processes? Chemical Society Reviews vol. 45 6478-6487 Preprint at https://doi.org/10.1039/c6cs00369a (2016).
46. Metzger, T. S. et al. The Electron Spin as a Chiral Reagent. Angewandte Chemie 132, 1670-1675 (2020).
47. Ghosh, S. et al. Effect of Chiral Molecules on the Electron's Spin Wavefunction at Interfaces. Journal of Physical Chemistry Letters 11, 1550-1557 (2020).
48. Michaeli, K. & Naaman, R. Origin of Spin-Dependent Tunneling Through Chiral Molecules. Journal of Physical Chemistry C 123, 17043-17048 (2019).
49. Ziv, A. et al. AFM-Based Spin-Exchange Microscopy Using Chiral Molecules. Advanced Materials 31, (2019).
50. Roushan, P. et al. Topological surface states protected from backscattering by chiral spin texture. Nature 460, 1106-1109 (2009).
51. Mtangi, W. et al. Control of Electrons' Spin Eliminates Hydrogen Peroxide Formation during Water Splitting. J Am Chem Soc 139, 2794-2798 (2017).
52. Kapon, Y. et al. Evidence for new enantiospecific interaction force in chiral biomolecules. Chem 7, 2787-2799 (2021).
53. Mtangi, W., Kiran, V., Fontanesi, C. & Naaman, R. Role of the Electron Spin Polarization in Water Splitting. Journal of Physical Chemistry Letters 6, 4916-4922 (2015).
54. Zhang, W., Banerjee-Ghosh, K., Tassinari, F. & Naaman, R. Enhanced Electrochemical Water Splitting with Chiral Molecule-Coated Fe3O4 Nanoparticles. ACS Energy Lett 3, 2308-2313 (2018).
55. R. Naaman, Y. Paltiel, D. Waldeck, Chiral molecules and the electron's spin. Nat. Rev. Chem. 3, 250-260 (2019).
56. D. Mishra, T. Z. Markus, R. Naaman, M. Kettner, B. Göhler, H. Zacharias, N. Friedman, M. Sheves, C. Fontanesi, Spin-dependent electron transmission through bacteriorhodopsin embedded in purple membrane. Proc. Natl. Acad. Sci. U.S.A 110, 14872-14876 (2013).
57. S. Mishra, S. Pirbadian, A. K. Mondal, M. Y. El-Naggar, R. Naaman, Spin-dependent electron transport through bacterial cell surface multiheme electron conduits. J. Am. Chem. Soc. 141, 19198-19202 (2019).
58. Y. Nie, L. Li, Z. Wei, Recent advancements in Pt and Pt-free catalysts for oxygen reduction reaction. Chem. Soc. Rev. 44, 2168-2201 (2015).
59. Saha, A. et al. Improved Cycling Stability of LiNi0.8Co0.1Mn0.1O2 Cathode Material via Variable Temperature Atomic Surface Reduction with Diethyl Zinc. Small 18, (2022).
60. Paula Yurkanis Bruice. Organic Chemistry. (Prentice Hall, 2001).
61. Ahn, J. & Yim, T. Ni-rich LiNi0.8Co0.1Mn0.1O2 oxide functionalized by allyl phenyl sulfone as high-performance cathode material for lithium-ion batteries. J Alloys Compd 867, (2021).
62. D. Wang, X. Pan, P. Yang, R. Li, H. Xu, Y. Li, F. Meng, J. Zhang, M. An, Transition metal and nitrogen Co-doped carbon-based electrocatalysts for the oxygen reduction reaction: from active site insights to the rational design of precursors and structures. ChemSusChem 14, 33-55 (2021).
63. X. Ge, A. Sumboja, D. Wuu, T. An, B. Li, F. T. Goh, T. A. Hor, Y. Zong, Z. Liu, Oxygen reduction in alkaline media: from mechanisms to recent advances of catalysts. ACS Catal. 5, 4643-4667 (2015).
64. X. Yang, J. Nash, N. Oliveira, Y. Yan, B. Xu, Understanding the pH dependence of underpotential deposited hydrogen on platinum. Angew. Chem. Int. Ed. 58, 17718-17723 (2019).
65. I. Meirzada, N. Sukenik, G. Haim, S. Yochelis, L. T. Baczewski, Y. Paltiel, N. Bar-Gill, Long-timescale magnetization ordering induced by an adsorbed chiral monolayer on ferromagnets. ACS Nano 15, 5574-5579 (2021).
66. D. H. Waldeck, R. Naaman, Y. Paltiel, The spin selectivity effect in chiral materials. APL Mater. 9, 040902 (2021).
67. S. Mishra, A. K. Mondal, S. Pal, T. K. Das, E. Z. Smolinsky, G. Siligardi, R. Naaman, Length-dependent electron spin polarization in oligopeptides and DNA. J. Phys. Chem. C 124, 10776-10782 (2020).
68. M. Shao, Q. Chang, J. P. Dodelet, R. Chenitz, Recent advances in electrocatalysts for oxygen reduction reaction. Chem. Rev. 116, 3594-3657 (2016).
69. J. Kim, A. A. Gewirth, Mechanism of oxygen electroreduction on gold surfaces in basic media. J. Phy. Chem. B 110, 2565-2571 (2006).
70. J. Fransson, Vibrational origin of exchange splitting and chiral-induced spin selectivity. Phys. Rev. B 102, 235416 (2020).
71. J. Fransson, Charge redistribution and spin polarization driven by correlation induced electron exchange in chiral molecules. Nano Lett. 21, 3026-3032 (2021).
72. Z. Zeng, T. Zhang, Y. Liu, W. Zhang, Z. Yin, Z. Ji, J. Wei, Magnetic field-enhanced 4-electron pathway for well-aligned Co3O4/electrospun carbon nanofibers in the oxygen reduction reaction, ChemSusChem 11, 580-588 (2018).
73. B. F. Minaev, Spin effects in reductive activation of O2 by oxydase enzymes. RIKEN Rev. 44, 147-149 (2002).
74. H. E. Lee, H. Y. Ahn, J. Mun, Y. Y. Lee, M. Kim, N. H. Cho, K. Chang, W. S. Kim, J. Rho, K. T. Nam, Amino-acid- and peptide-directed synthesis of chiral plasmonic gold nanoparticles. Nature 556, 360-365 (2018).

Acknowledgement of the above references herein is not to be inferred as meaning that these are in any way relevant to the patentability of the presently disclosed subject matter.

### BACKGROUND

The work function of the surface of any material, solid or liquid, is defined as the minimum amount of energy required to move an electron from the interior of the material to infinity. The work function measured for a particular material will vary if contaminants or coatings are present. There are various methods for measuring the work function of a surface, like photoelectrons spectroscopy in which electrons are injected from the material with well-defined photon energy and the electrons' energy is determined. Another method is the Kelvin probe. The Kelvin Probe is a non-contact, non-destructive measurement device. It is based on a vibrating capacitor and measuring the surface potential difference between the studies surface and a vibrating reference surface.

A large number of charge storage devices (e.g. thin film batteries) and electronic devices (e.g. organic thin-film optoelectronic devices including organic light-emitting diodes (OLEDs), organic thin-film transistors (TFTs) or organic solar cells (OSCs)), require at least one electrode material which exhibits a work function that is sufficiently low to either inject electrons into or collect electrons from the lowest unoccupied orbital (LUMO).

In terms of materials having a low work function, various metals, such as Li, Na, Mg, Ca or Zn, for example, represent suitable candidates for such electrodes. However, low-work function electrode layers are usually applied by using thermal evaporation or sputtering, which is expensive, complicated and not readily applicable to many metals, such as Zn. In addition, these electrodes must be handled in high vacuum and necessitate elaborate equipment due to the high reactivity of the pure metals towards air and water.

Different strategies have been proposed to solve at least some of those problems. For example, Zhou et al., Science 2012, 336 (2) 327-336 disclose that the work function of conductors may be reduced by modifying their surface with polyethyleneimines, which allows the use of alternative electrode materials that are less prone to oxidation. However, this method requires an additional manufacturing step, and it still remains difficult to achieve a work function as low as that of pure alkali metals, for example, by using this method. An alternative approach is taken in US 2005/0019976. Herein, electrodeposition and printing techniques which do not require vacuum environments are disclosed. Also, WO 2008/127111 proposes a method of manufacturing an electrode by electrodeposition, in which a plating liquid comprising an ionic liquid and metal, or metalloid ions is applied, so that the latter are reduced and deposited to form an electrode on the surface of an electro-active substance. However, these methods require a drying step and elaborate processing of the formed electrodes under inert gas atmosphere so as to avoid contact with air and water. Moreover, the possible device configurations obtainable by these methods are limited in terms of electrode placement, since due to the reactivity of the electrode material towards residual solvent (e.g. water), the deposition of solution-processed layers on top of the electrode material (or alternatively the deposition of the electrode on top of a solution-processed layer) is either not possible or results in a non-uniform and deteriorated electrode layer. WO 2013/019993 relates to a method of enhancing charge injection by providing an isopotential source layer comprising non-reducible mobile ions.

Lithium-ion batteries (LIBs) are the most common type of electrochemical energy storage used in a variety of industries, including electric vehicles, phones, portable electronics, and stationary grid power stations [1,2]. They are known for their high energy density, reliability, and efficiency [3-6]. Nickel-rich layered lithium transition metal oxides are a promising cathode material for next-generation LIBs used in automotive applications because of their high specific capacities (200-250 mAh/g), high working voltage (around 3.6-3.8 V), good rate capability, and relatively low cost [7-9]. The chiral organic coating of the active LiNi_{0.8}Mn_{0.1}Co_{0.1}O₂ (NMC811) material enhances the discharge capacity and the rate capability and reduces the material retention.

However, these materials can suffer from structural and interfacial instability during repeated charge and discharge, leading to deterioration in performance and safety concerns. One issue is that the highly reactive materials can accelerate the decomposition of electrolytes, resulting in rapid capacity fading and overall poor battery performance [7,10]. Internal resistance and overpotential also play a crucial role in battery performance. Low electronic resistance leads to higher power density and decreased risk of overheating, while low overpotential results in higher energy density [11].

The capacity fading and relative insufficient rate capability would become severe effects due to the high Ni-content presence in NMC811 cathode materials at higher cut-off voltage (>4.4 V vs Li+/Li) operation [12]. The significant reasons for the capacity fading can be attributed to the structural degradation induced by (i) the accumulation of NiO-phase on the surface, (ii) the lithium residue on the surface which can easily absorb H₂O and CO₂ to generate Li₂CO₃ and LiOH, resulting in high pH and high interface resistance of cathode material, (iii) the most important factor on continuous electrochemical reactions during charge-discharge which induces the parasitic by product HF formation in the electrolytes which dissolves the transition metal ions on NMC materials [13,14]. The undesired transition metal dissolution from the cathode could destroy the structural stability of the cathode active materials and alter the composition of solid electrolyte interphase (SEI) [15].

It is therefore not surprising that large efforts have been reported in the literature targeting to reduce degradation and enhance battery performance. A promising approach utilizes surface modification of the cathode material by a coating process [16,17]. This approach aims to address capacity fading of Ni-rich cathode materials during long charge-discharge cycling. The protective surface modification includes both cathode and anode surface coating using core-shell structural design by wet chemical methods [18], physical vapor deposition [19], chemical vapor deposition [20], atomic layer deposition [21,22]. The surface treatment can protect the contact between NCM cathode materials and electrolyte, suppressing transition metal dissolution from the cathode and reducing side reactions for improving the electrochemical performance in terms of rate capability, retention of specific capacity, and long-term cycling [23,24]. Moreover, the coating may reduce micro cracks and oxygen release which would accompany these changes after long cycling of charge and discharge which brings in safety defects.

This approach was widely investigated in Lithium-ion batteries with stable transition metal, metal oxides such as Al₂O₃, SiO₂, TiO₂, ZnO, ZrO₂, phosphates (AlPO₄, Li₃PO₄), and fluorides (AlF₃) [25,26], polymeric materials and metal organic frame work (MOF) [28,29] protected on cathode materials for resisting abilities to avoid the direct electrode-electrolyte contact and corrosion of HF on cathode materials during long charge-discharge cycles. However, most of these inorganic coating materials have impecunious electrical conductivities and parasitic byproduct formation with lithium and cathode materials which show an antipathetic effect on the electrochemical performance. In addition, most of these coating materials are Li⁺ ion insulators, which inhibit the diffusion of Li⁺ ions in the cathode material and therefore do not utilize its full capacity.

Controlled oxygen reduction reaction (ORR) is central for aerobic life [29] and for developing clean energy technologies like fuel cells [31,32]. The process starts with oxygen in a triplet ground state and ends with products that are all in singlet states. Hence, spin constraints in the oxygen reduction are to be overcome. Typically, this has been done by using electrode with large spin orbit coupling (SOC).

Understanding the detailed mechanism of the ORR is challenging, because one must consider spin selection rules: the ground state of a diatomic oxygen is in a triplet electronic state (³Σ_{g}) while the reaction products are in closed shell singlet states. Indeed, current fuel cell technologies use rare metal catalysts, which possess significant spin-orbit coupling. In contrast, aerobic organisms perform the ORR without the need for precious metals. While some enzymes possess metal co-factors with significant spin-orbit couplings that may relax spin constraints in the reaction [33]), enzymes without metal cofactors are known to facilitate the efficient reduction of oxygen [34,35]. It seems clear that important subtleties of the biochemical mechanism remain elusive.

The intrinsic activity of ORR catalysts has not been improved significantly and there has been limited success in developing catalysts with lower overpotential [36]. The best ORR catalysts are platinum-based, and the adsorption of oxygen on the catalyst is very efficient at low reduction potentials, so that the proton and electron transfer are inefficient. Only at high reduction potentials, the reaction can proceed due to the decreased stability of the adsorbed oxygen [37,38]. This has been considered as the origin of the observed ORR overpotential, and a crucial bottleneck in catalyst development.

### GENERAL DESCRIPTION

There is a need to provide a method of preparation of surfaces having low work function. In particular, there is a need to provide an inexpensive and simple method for the preparation of low work function electrodes, which may be used to manufacture a large variety of device configurations. This enables to provide inter alia electronic devices and/or charge storage devices with improved charging times.

The presently disclosed subject matter relates to a new technique for controlling surfaces work function by depositing a chiral system. Chirality is a property of objects that cannot be superimposed onto their mirror image, much like left and right hands. Chiral molecules are essential in chemistry and biology as they can have different properties and reactivity compared to their mirror image [44,45]. The term “chiral system” refers hereinafter to molecules having a non-superimposable mirror image (i.e. enantiomers). The chiral system can be chiral on the molecular level (intrinsically chiral) or chiral due to the structure of a formation of several molecules (each itself not intrinsically chiral). In some embodiments, it may include homo-chiral or one-directional chiral molecules in which all the chiral molecules in a given sample have the same chirality or handedness (e.g. either left-handed or right-handed, but not a mixture of both.) The surfaces, or parts of the surfaces are made of, or coated with chiral materials. It has been found that chemically bonding a chiral system to a surface or physically adsorbing the surface with a film of chiral material (either molecules or inorganic material), changes the surface work function. This allows the electrons to leave or enter the surface at a lower potential than for another surface such as a bare electrode or an electrode coated with achiral film. Therefore, the utilization of chiral coating of surfaces enables reducing their work function. As described above, the adsorption of molecules on surfaces changes their work function due to the change in the dipole moment perpendicular to the surface. In addition to the simple change of the dipole moment, the presence of chiral molecules induces spin polarization in magnetized substrate resulting in making transfer of electrons with one spin preferable and with less resistance at the substrate-molecule interface as described in [39]. [39] describes Kelvin-probe measurements on ferromagnetic thin film electrodes coated with self-assembled monolayers of chiral molecules revealing that the electron penetration from the metal electrode into the chiral molecules depends on the ferromagnet's magnetization direction and the molecules' chirality. The change in the work function in the magnetic electrode described in is due to the change in the magnet direction of the electrodes. However, using magnetic or ferromagnetic electrodes in electrochemical systems is not practical, it is expensive and very limited with respect to the manufacture of a variety of device configurations. Moreover, despite the change in the work function of the magnetic electrode, the use of magnetic or ferromagnetic coated electrodes does not allow electrons to leave or enter the magnetic or ferromagnetic coated electrode at lower potential and/or resistance than for a non-coated magnetic electrode.

The unique approach of the inventors involves molecular chiral coating which is known to enable pure spin current as a result of the chiral-induced spin selectivity (CISS) effect [40-43]. The CISS effect is a phenomenon where the spin state of electrons passing through a chiral molecule is selectively affected by the molecule's handedness [40,42,46,47]. In other words, the spin of electrons passing through a left-handed molecule differs from the spin state of electrons passing through a right-handed molecule [30,32]. Thus, charge displacement and transmission in chiral molecules generate a spin-polarized electron distribution [48,49]. Spin-polarized electron cannot backscatter in the chiral potential and therefore the resistance is reduced [50]. The electron spin is also critical in chemical reactions where most bonds are in a singlet state [51,52]. However, the oxygen molecule is special with a triplet state in the ground energy level [51]. Therefore, standard oxidation processes are spin forbidden and have large overpotential. In these cases, the CISS effect can be utilized to align multiple electron spins enabling to enhance the efficiency of these processes [53], as will be described in more detail further below in relation to the oxygen reduction reaction. Similarly, spin alignment can be utilized to increase the employment of spin selective current in electrolyzers, fuel cells, improving their efficiency. Indeed, it was demonstrated by the inventors that using chiral molecules, as intermediaries in water splitting can increase efficiency by lowering the overpotential by 50% [53,54]. In the present disclosure, the electrochemical properties of chiral L-alpha-helix Polyalanine (AHPA), [H]-C(AAAAAK)7-[OH], achiral 12-mercaptododecanoic acid (MDA), both purchased from Sigma Aldrich, Ltd. Israel, and pristine cathode materials were compared. The chiral molecules coated the active material with results indicating an increase in specific capacitance at both low and high charge and discharge rates using the chiral coating. Specifically, the AHPA-chiral coated NCM811 cathode material enhances efficiency by 6%, decreasing the overpotential by 0.1V in the reduction process and reducing the energy loss and heating obstacles.

The present disclosure presents a technique for reducing the internal resistance and the work function of surfaces and improving the efficiency of electron transfer. This may be implemented by providing electrodes and coating for electrodes made of or coated with chiral materials. The presence of chiral molecules induces electron spin polarization resulting in more efficient transfer of electrons with one spin and with less resistance at the interface. The inventors of the present disclosure provide novel electrodes and coating for electrodes and electrode components that show improved efficiency of electron transfer.

This technique can be used for enhancing the operation of any one of the following devices: batteries, electrolyzers, fuel cells, switches, connectors, electrochemical capacitors, photovoltaic (PV) cells, and devices in which the Schottky barrier should be controlled. The chiral molecules and chiral organic and inorganic films may be used for controlling the electrode-electrolyte interface in electrochemical systems, thereby adjusting the surface work function and/or spin state at the electrode-electrolyte interface so as to optimize the operation of the electrochemical system.

According to another aspect of the present disclosure, there is provided a method for controlling a work function of at least one surface comprising measuring a first work function of a first surface; depositing a chiral system on the first surface to cause change in the certain first work function, applying a potential difference between the first surface and a second surface so as to create transfer of electrical charges between the first and second surfaces, measuring a second work function of the first surface carrying the chiral system; wherein the second work function is lower than the first work function. The interaction between the chiral system and the first surface is configured to cause charge spatial rearrangement on the first surface, spin polarization of the first surface, and spin polarization of electrons being injected from or to the first surface, thereby modifying the work function of the first surface, allowing electrons to leave or enter the first surface at lower potential energy and/or reducing the electrical resistance of the first surface to be lower than the electrical resistance of the first surface before the deposition of the chiral system.

In some embodiments, depositing the chiral system on the first surface comprises chemically bonding of the chiral system to the first surface or physically adsorbing the chiral system on the first surface.

In some embodiments, when the first surface at least partially carrying the chiral system is configured and operable as a working electrode and the second surface is configured and operable as a counter electrode, the method further comprises interacting at least one chiral coated surface with an electrolyte to be used as an electrode and another surface as counter electrode before applying the potential difference. The interaction between the chiral electrode and the electrolyte being configured for changing a spin state at an electrode-electrolyte interface.

In some embodiments, the method further comprises immersing the at least one electrode and the counter electrode in an electrolyte before applying the potential difference, the interaction between the chiral electrode and the electrolyte being configured for changing a spin state at an electrode-electrolyte interface.

According to another broad aspect of the present disclosure, there is provided an electrode for use in an electrochemical process. The electrode comprises a substrate having an electrically conductive surface carrying a chiral system, wherein the chiral system is configured for controlling a work function of the electrode. The interaction between the chiral system and the electrode is configured to cause charge rearrangement, spin polarization of the electrically conductive surface and spin polarization of electrons being injected from or to the electrically conductive surface so as to reduce the work function of the electrode and the potential energy for starting the electrochemical process and the electrical internal resistance of the electrode.

The chiral system may comprise at least one of organic and inorganic matter having chiral properties or any combination thereof. The chiral system may comprise a chiral polymer and/or a chiral inorganic film. The chiral system may be configured as a single- or multi-layer structure operating as a layer improving charge separation. It may also comprise a self-assembled monolayer of the chiral molecules, or chiral biomolecules. The chiral system may be either chemically bound to the surface of the substrate or physically adsorbed on it. The substrate may be made of at least one of metal chiral conductor and semiconductor.

In some embodiments, the chiral system comprises at least one of the following chiral organic materials: polypeptides, oligopeptides, amino acids, proteins, DNA, helicenes, chiral polymer, small chiral molecules or any combination thereof or the following chiral inorganic material: chiral oxides, chiral metals, and chiral crystals or any combination thereof. The term “small chiral molecules” refers to molecules having a thickness being less than 10 nm.

In some embodiments, the chiral system comprises chiral metal or semiconductor nanoparticles, for example at least one of gold, silver, palladium, platinum, CdS, or perovskites nanoparticles or any combination thereof.

In some embodiments, the electrode is configured as a photoabsorber. Additionally or alternatively, the substrate may be configured as a photoabsorber.

In some embodiments, the electrode comprises at least one layer of photoabsorber carried by the substrate. The chiral system may comprise at least one layer of photoabsorber having chiral properties.

In some embodiments, the electrode comprises photoabsorbing nanoparticles bound to the substrate via the chiral system.

According to another broad aspect of the present disclosure, there is provided an electrochemical cell system comprising an electrochemical cell being configured to at least one of: electrolyze at least a first electrolyte or converting a chemical energy of a fuel into electricity and the electrode as defined above, wherein the electrode carries the chiral system and is configured to interact with a first electrolyte of an electrochemical system. The interaction between the chiral electrode and the first electrolyte is configured for changing a spin state at an electrode-electrolyte interface so as to optimize the operation of the electrochemical system. The optimization of the operation of the electrochemical system may be implemented, for example by reducing the impedance of the cell and improving the number of charging cycles.

In some embodiments, the electrochemical cell further comprises a counter-electrode connectable to the chiral electrode and being configured to interact with a second electrolyte being in chemical communication with the first electrolyte, wherein a potential energy is capable of being applied between the chiral electrode and the counter-electrode. The counter-electrode may comprise a substrate having an electrically conductive surface at least partially carrying a chiral system. The substrate may be made of at least one of metal, chiral conductor and semiconductor. The first and second electrolyte may be made of the same or different material.

In some embodiments, the electrochemical cell further comprises a membrane being configured to create a separation between the first and second electrolyte.

In some embodiments, the membrane comprises a substrate having an electrically conductive surface at least partially carrying a chiral system as defined above. The substrate may be made of at least one of metal, chiral conductor and semiconductor.

There is a need in the art for a novel approach for the oxygen reduction reaction (ORR) enabling to lower the overpotential of the reduction reaction. Overpotential is an electrochemical term which refers to the potential difference between a half-reaction's thermodynamically determined reduction potential and the potential at which the reaction is experimentally observed, and thus describes the cell voltage efficiency. Overpotential is a common problem of the oxygen reduction system because the system typically needs a relatively high potential onset as compared to the working potential, i.e., equilibrium potential of the net redox reaction.

The present disclosure provides electrodes and coating for electrodes to be used in an oxygen reduction system (e.g., fuel cell system). Such electrodes are characterized by improved efficiency of electron transfer to oxygen (oxygen reduction reaction) and enhanced operation even for electrodes having large SOC. The electrodes of the present disclosure are either made from a chiral conductor or from a conductor coated with a chiral material/structure. The inventors demonstrated lower overpotentials and higher current densities for chiral catalysts versus achiral ones. The effect results from the spin selectivity conferred on the electron current by the chiral assemblies, the chiral induced spin selectivity effect.

The inventors assume that the multielectron reduction of diatomic oxygen (ORR) is enhanced by the use of spin polarized electrons and that chiral biomolecules, which are known to spin polarize electrons via the chiral induced spin selectivity (CISS) effect [55], can be used to enhance the ORR efficiency. Previous work demonstrates that electron transport through proteins is spin dependent [56], including proteins involved in respiration [57].

The inventors examined the electrochemical ORR at electrodes modified with chiral organic monolayers tested the effect of chirality on metallic thin films and on platinum and gold nanoparticles. In each case, the inventors compared the ORR performance of the chiral modified electrodes, particularly the onset potential and the current densities, to the same of their achiral analogues. Platinum nanoparticles were specifically chosen because they are the preferred catalyst in fuel cells [58]. In some embodiments, the electrochemical cell system is configured to be immersed in a solution containing oxygen and being operable to enhance electron transfer from the electrodes to oxygen and to lower an overpotential of an oxygen reduction reaction.

The sharp rise in energy demands and green energy interest dramatically enhances the need for energy storage devices. Lithium-ion batteries (LIBs) are the most common type of electrochemical energy storage used in a variety of industries, including electric vehicles, phones, portable electronics, and stationary grid power stations. Among those, Nickel-rich layered lithium transition metal oxides (LiNi_{1-x-y}CoₓMn_{y}O₂) are one of the promising cathode materials for next-generation lithium-ion battery applications due to their specific capacities and high working voltage. However, these materials suffer from structural/interfacial instability, resulting in, among others, safety concerns. In the present disclosure, the inventors demonstrated that a thin layer coating of polyalanine chiral molecules can protect and improve the performance of Ni-rich cathodes. Specifically, NMC811 electrodes coated with chiral molecules exhibit lower voltage hysteresis and better rate performance. The inventors relate these results to the chiral-induced spin selectivity (CISS) effect that enables to reduce the resistance of the electrode interface and reduce dramatically the overpotential needed for the chemical process by aligning the electrons spins.

Therefore, according to another broad aspect of the present disclosure, there is provided an energy storage device (e.g. a source of electric power system) comprising at least one electrochemical cell as defined above, an electric module for applying a potential difference between the electrode and the counter-electrode connectable to the electrode for at least one of charging and discharging the energy storage device, wherein the energy storage device is configured to cause a reduction in the potential difference being applied between the electrode and the counter electrode for at least one of charging and discharging the energy storage device due to the interaction between the chiral system and the electrode causing charge rearrangement, spin polarization of the surface, and spin polarization of electrons being injected from or to the surface.

In some embodiments, at least one of the first and second electrolyte comprises active materials being a chiral material.

In some embodiments, the energy storage device is configured as an electrical battery.

In some embodiments, the energy storage device is configured as an electrochemical capacitor.

The technique is directed to processes with improved work function of a surface covered with chiral molecules, and corresponding uses, inter alia, energy storage devices such as batteries with improved charging times or other electrochemical processes involving for example electrochemical cells operating as electrolyzers (e.g. hydrogen, aluminum chlorin electrolyzers). Therefore, in some embodiments, the presently disclosed subject matter relates to a method of use in batteries and to the batteries themselves. As electrons flow from one material to another in the battery cell, the spin of such electrons has an effect on the work function and the internal resistance. The reduction of the work function and the internal resistance of batteries and battery components are important aspects in the overall performance of the battery. In particular, reducing the internal resistance of such energy storage devices can lead to more efficient electrochemical reactions, reducing resistivity waste, and increasing the energy storage device performance (e.g. capacity, charging time, reduced temperatures and more). The batteries may be rechargeable batteries or disposable batteries.

According to another broad aspect of the present disclosure, there is provided a method of use of the electrode as defined above in an electrochemical system. The method comprises interacting between the electrode (i.e. anode) and an electrolyte of the electrochemical system and passing an electrical current into the electrolyte from the electrode, so as to cause charge rearrangement, spin polarization of the surface, and spin polarization of electrons being injected from or to the surface thereby reducing the work function of the chiral electrode, the interaction between the chiral electrode and the electrolyte being configured for changing a spin state at an electrode-electrolyte interface so as to optimize an operation of the electrochemical system.

According to another broad aspect of the present disclosure, there is provided a photovoltaic cell module comprising at least one photovoltaic cell being configured and operable to receive light, convert energy of the received light into electrical energy and generate electrical power; at least a pair of electrodes electrically coupling the photovoltaic cell and being configured and operable to collect the electrical power; and a layer having an electrically conductive surface at least partially carrying a chiral system, the layer being placed in between the at least one photovoltaic cell and the at least a pair of electrodes and being configured and operable to enhance the performance and the efficiency of the photovoltaic cell module. In this connection, it should be noted that under sunlight illumination, excitons are generated in the active area of the photovoltaic cell (Si solar cells for example). Charge separation between the excited electrons and holes is critical for achieving high operation efficiency. This is often achieved by realizing P/N or P/I/N junctions. The doping of the active area is therefore critical in all photovoltaic cells but is also generating a mechanism of loss due to non-radiative recombination decay in the active area. These scattering effects reduce cell efficiency. The excited electrons travel to the current collectors and through an external electrical circuit, generating an electrical current. Electron-hole recombination rate is a critical factor in photovoltaic cell efficiency. Another loss mechanism is generated by the over potential barriers that charges need to cross before entering the electrode/current collectors. The novel technique of the present disclosure is capable of reducing the electrodes over potential at the current collectors and enhancing charge separation efficiency while decreasing recombination loss.

Semiconductors, such as silicon, are orders of magnitude less conductive than metals. To increase the likelihood of an electron reaching the current collector and through it the external circuit, most cells utilize metal-based contacts/current collectors. Often, the top contacts would be with a grid pattern (as it needs to transfer electricity out of the cell while passing light into it). The bottom contact would often be a full metal “sheet”. The key design trade-off in top contact design is the balance between the increased resistive losses associated with a widely spaced grid and the increased shading caused by narrow spacing. The interface between the semiconductor cell and the metal contact is another parameter affecting the losses via contact resistivity, current crowding (a driver of additional resistivity) at the edges of the contact, and recombination at the contact. Reducing the resistance at the metal-contact and semiconductor interface can lead to more efficient photovoltaic cells with less recombination and resistivity losses, increasing overall cell performance. As electrons flow from the semiconductor to the contacts, the spin of such electrons influences the resistance at the interface. Aligned spins reduce resistivity and allow more electrons to pass to the external circuit.

In the present disclosure, the inventors provide contacts and coatings for photovoltaic cell contacts that show improved efficiency of electron transfer. The contacts, or parts of the contacts are made of, or coated with a chiral system. The chiral system enhances spin selectivity by the CISS effect, and the aligned spins drive lower resistivity thus reducing the electrodes over potential at the current collectors). Moreover, the presence of chiral molecules on both the positive and negative contacts reduces recombination of electron and hole pairs as a result of charge separation. Similar charge separation occurs if the positive and negative contacts are chiral, thus enhancing charge separation efficiency while decreasing recombination loss.

In some embodiments, at least one electrode of the photovoltaic cell module comprises a substrate having an electrically conductive surface at least partially carrying a chiral system. The chiral system of the photovoltaic cell module may be as defined above. The substrate of the photovoltaic cell module may be made of at least one of metal, chiral conductor and semiconductor.

According to another broad aspect of the present disclosure, there is provided an electrical component comprising a substrate having an electrically conductive surface at least partially carrying a chiral system, wherein the chiral system is configured for controlling a work function of the electrical component, the interaction between the chiral system and the electrical component causing charge rearrangement, spin polarization of the surface and spin polarization of electrons being injected from or to the surface so as to reduce the work function of the electrical component, and the electrical internal resistance of the electrical component. The chiral system may be as defined above. The substrate of the electrical component may be made of at least one of metal, chiral conductor and semiconductor.

In some embodiments, the electrical component is configured as an electrical switch being configured to control the flow of electricity of an energy source.

In some embodiments, the electrical component is configured as an electrical connector being configured to electrically couple a plurality of electrical circuits.

### BRIEF DESCRIPTION OF THE DRAWINGS

In order to better understand the subject matter that is disclosed herein and to exemplify how it may be carried out in practice, embodiments will now be described, by way of non-limiting example only, with reference to the accompanying drawings, in which:

FIG. 1 is a flow chart illustrating the main steps of the method for controlling a work function of at least one electrode according to the teachings of the presently disclosed subject matter;

FIG. 2 is diagram showing the different work functions obtained for different electrodes being made of gold, gold coated with a monolayer of L-cysteine, gold coated with a monolayer containing a mixture of L and D enantiomers of cysteine, and gold coated with a monolayer of 3-mercaptopropionic acid (MPA);

FIG. 3 is a schematic illustration of an electrode and of the mechanism affecting the work function of the electrode surface according to the teachings of the presently disclosed subject matter;

FIGS. 4A-4B show a specific and non-limiting example illustrating a possible use of the electrode of the presently disclosed subject matter in an electrochemical system, in particular, FIG. 4A shows a schematic illustration of a possible electrochemical cell and FIG. 4B shows the potential barrier over time of different configuration of electrochemical cells;

FIG. 5 shows the manufacturing process scheme of coating the active material of the battery with chiral molecules;

FIGS. 6A-6I describe the characterization electrode material particles coated with chiral molecules, in particular FIGS. 6A-6D show XPS spectra of S 2p (FIG. 6A), N 1s (FIG. 6B), Co 2p (FIG. 6C), and Ni 2p (FIG. 6D) in samples chiral-A, Chiral-B, Achiral-C, and Pristine NCM811; FIG. 6E shows XRD diffraction peaks of the NCM powder samples in the 2θ range of 10°-80°; FIGS. 6F-6I show high-resolution SEM images of the powder samples, FIGS. 6F-6G show, respectively, high and low magnification images of sample Chiral-A, and FIGS. 6H-6I show, respectively, high and low magnification images of sample Pristine NCM811;

FIGS. 7A-7C show electrochemical measurements of Chiral-A, Chiral-B, Achiral-C, and Pristine NCM811/Li half-cells for I-V profiles (FIG. 7A), Discharge capacity rates profiles (FIG. 7B), and Cyclic stability performance at 1C-rate (FIG. 7C); All measurements were performed at 35° C. in 1 M LiPF6 EC/EMC (3:7) electrolyte solution;

FIGS. 8A-8H show Postmortem Analysis: SEM and EDX spectra of cycled electrodes at 1C-rate of FIGS. 8A-8C Chiral-A and FIGS. 8D-8F Pristine-NCM811; FIG. 8G shows a comparative XRD pattern of pre- and post-cycling electrodes of Chiral-A and P-NCM811 samples, FIG. 8H shows selective XRD pattern of (003) plane;

FIG. 9 shows a schematic layout of the electrochemical setup, which includes a gold working electrode coated with a self-assembled monolayer (SAM) of either chiral or achiral molecules;

FIGS. 10A-10C show spectra obtained by polarization modulation-infrared reflectance-absorption spectrometer (PM-IRRAS) characterizing the monolayer formation on the gold electrodes, in particular FIG. 10A shows spectra of 3-mercaptopropionic acid (achiral) and L-cysteine (chiral) coated Au surfaces; FIG. 10B shows spectra of various achiral alkanethiols used in the experiments; and FIG. 10C shows spectra of various chiral oligopeptides used in the experiments;

FIGS. 11A-11C show oxygen reduction activity of molecules-coated electrodes, in particular FIG. 11A shows the current versus potential measured when the electrode was coated with a monolayer of achiral molecules (the achiral 3-mercaptopropionic acid, blue curves), or the chiral molecules (L-cysteine, red curves) in N₂ (dotted curves) and O₂ (solid curves)-saturated 0.1 M KOH solution; FIGS. 11B-11C show the current versus potential measured when the electrode is coated with a monolayer of achiral molecules (1-octadecanethiol) (FIG. 11B), and chiral oligopeptides (L-ala5) in N₂ (dotted curves) and O₂ (solid curves)-saturated 0.1 M KOH solution (FIG. 11C);

FIG. 12 shows current versus potential for three electrodes, commercial Pt/C, achiral Pt NPs and chiral Pt NPs electrodes;

FIGS. 13A-13D show the molecular length-dependent oxygen reduction, in particular FIGS. 13A and 13B show, respectively, the current versus potential curves for monolayers of achiral (FIG. 13A) and chiral (FIG. 13B) molecules of various lengths; FIGS. 13C and 13D show, respectively, the onset potentials versus molecular length for working electrodes modified with achiral (FIG. 13C) and chiral (FIG. 13D) monolayers of different lengths;

FIGS. 14A-14D describe resistance characterization of chemically coated electrodes; in particular the cyclic voltammetry curves obtained for the electrode coated with either achiral (FIG. 14A) or chiral (FIG. 14C) monolayers; FIGS. 14B and 14D show the peak current densities of the long and short molecules are presented for the achiral (FIG. 14B) and chiral (FIG. 14D) molecules, respectively;

FIGS. 15A and 15B show electrochemical impedance spectra of (FIG. 15A) achiral (1-decanethiol, 1-octadecanethiol) and chiral molecules (L-ala3, L-ala7) coated surfaces within a three-electrode system (FIG. 15B); FIG. 15C shows an equivalent circuit model employed to fit the electrochemical impedance spectra; FIG. 15D is a summary of the Rₛ and R_{ct} values estimated from the equivalent circuit model;

FIGS. 16A and 16B show circular dichroism spectra (FIG. 16A) and UV-visible absorption spectra (FIG. 16B) of synthesized gold (Au) films with L- or DL-tartaric acid; FIG. 16C shows ORR performance of the synthesized Au thin films;

FIGS. 17A and 17B show circular dichroism spectra (FIG. 17A) and UV-visible absorption spectra (FIG. 17B) of synthesized gold nanoparticles (Au NPs) with L- or DL-cysteine; FIG. 17C shows the current vs potential measured with gold nanoparticles (Au NPs) of different chirality;

FIGS. 18A-18D show characterization of the morphology of Pt nanoparticles (NPs), in particular FIGS. 18A and 18C show Transmission Electron Microscope (TEM) images and FIGS. 18B and 18D show size distributions of Pt NPs modified with the L-(FIGS. 18A, 18B) or DL-cysteine (FIGS. 18C, 18D);

FIGS. 19A and 19B show circular dichroism spectra (FIG. 19A) and UV-visible absorption spectra (FIG. 19B) of synthesized Pt nanoparticles (Pt NPs) with L- or DL-cysteine; FIG. 19C shows ORR performance of Pt NPs; FIGS. 19D-19F show electrochemical properties of Pt catalysts in which cyclic voltammetry (CV) curves of chiral (FIG. 19D) and achiral Pt NPs (FIG. 19E), and commercial Pt/C catalyst in N₂-saturated 0.1 M KOH (FIG. 19F), FIG. 19G shows the current vs potential measured with platinum nanoparticles (Pt NPs) of different chirality, commercial Pt/C catalyst was added for comparison;

FIGS. 20A-20F show the effect of chiral molecules, in particular FIG. 20A shows the dependence of the spin polarization on the length of the chiral oligopeptides; FIG. 20B shows results of calculation for the number of electrons transferred, specifically, the current versus potential measured with monolayers of L-ala3 and L-ala7 in O₂-saturated 0.1 M KOH electrolyte at a scan rate of 50 mV/s; FIG. 20C shows the splitting in the spin states of the triplet oxygen upon interaction with the spin polarized electrons residing on the chiral molecules; FIGS. 20D and 20E show the possible spin states in the case of a chiral system (FIG. 20D) and in the case of an achiral one (FIG. 20E); and FIG. 20F shows the calculated triplet energy levels on the oxygen presented as a function of distance between the chiral molecule and the oxygen;

FIG. 21 shows a possible configuration of an energy storage device comprising an electrochemical cell configured as a battery, in which each of the battery electrodes comprises a respective substrate having an electrically conductive surface and carrying a respective chiral system according to the principles of the present disclosure;

FIG. 22 shows a possible configuration of a photovoltaic cell module comprising a photovoltaic cell, in particular each one of the photovoltaic cell's electrodes comprises a respective layer having an electrically conductive surface at least partially carrying a chiral system according to the principles of the present disclosure;

FIGS. 23A and 23B show possible configurations of electrical components comprising a substrate having an electrically conductive surface at least partially carrying a chiral system, in particular FIG. 23A shows a junction field-effect transistor (JFET) in which chiral coating covers the electrodes of the gate, source and drain terminals; and FIG. 23B shows an interconnect comprising metal, magnetic or superconductor layers and two contacts/electrodes in which a chiral coating is lining the interface between the outer surface of the metal, magnetic or superconductor layers and the contacts/electrodes;

FIGS. 24A and 24B show possible configurations of energy storage devices being configured as electrochemical capacitors, in particular the electrochemical capacitor of FIG. 24A comprises two electrodes separated by an ion-permeable membrane (separator), each one of the electrodes is coated with a chiral system according to the principles of the present disclosure; and the electrochemical capacitor of FIG. 24B comprises two charged conductive plates, one of the plates is positively charged and one of the plates is negatively charged with a dielectric layer separating the conductive plates; each one of the conductive plates is coated with a chiral system according to the principles of the present disclosure; and

FIGS. 25A and 25B show, respectively, two possible configurations of electrochemical cell systems, in particular FIG. 25A shows an electrochemical cell configured as a water electrolyzer comprising two electrodes, an anode and a cathode, both carrying a chiral system according to the principles of the present disclosure; and FIG. 25B shows an electrochemical cell configured as a fuel cell, the two electrodes, an anode and a cathode of the cell are carrying the chiral system as described in the present disclosure.

### DETAILED DESCRIPTION OF EMBODIMENTS

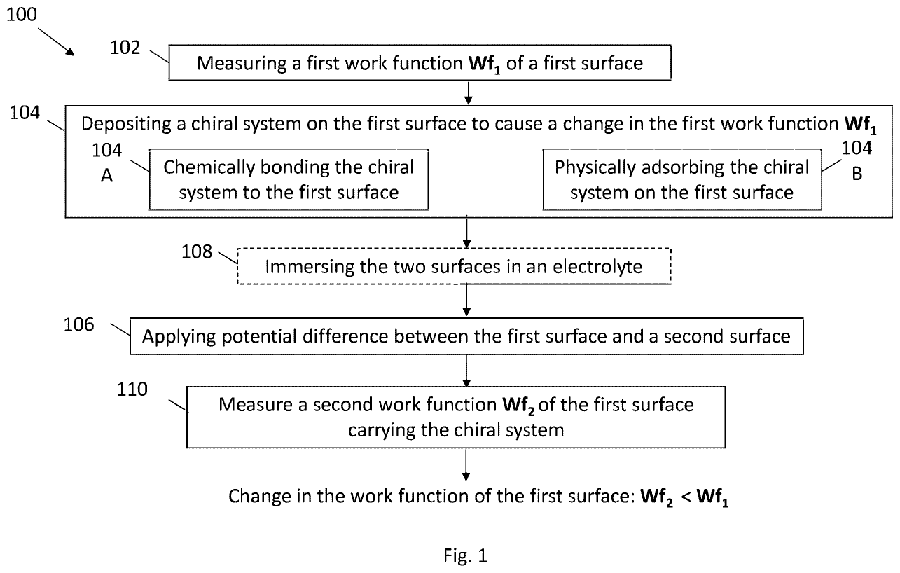

Reference is made to FIG. 1 showing a method 100 for controlling a work function Wf of at least one surface. The method 100 comprises measuring a first work function, Wf₁, of a first surface in 102, depositing in 104 a chiral system on the first surface to cause change in the first work function Wf₁, applying in 106 a potential difference between the first surface and a second surface such that to create a charge transferred between the first and second surfaces. The interaction between the chiral system and the first surface is configured for causing charge rearrangement, spin polarization of the first surface, and spin polarization of electrons being injected from or to the first surface thereby modifying the work function Wf₁f of the first surface. Depositing the chiral system on the first surface in 104 may comprise chemically bonding the chiral system to the first surface in 104A, like the case of binding thiols to gold, or physically adsorbing the chiral system on the first surface in 104B like in case of deposition of chiral oxides.

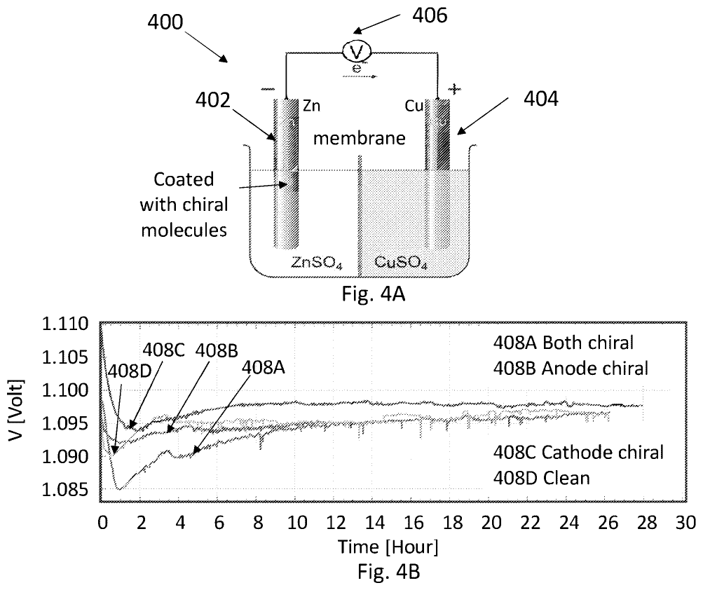

If the technique of the present disclosure is implemented for improving an electrochemical process in which the first and second surfaces are utilized as first and second electrodes, the passage of an electric current between the two electrodes involves an electrochemical reaction and transfer of electrons between two substances, the method 100 may further comprise immersing in 108 the first surface and the second surface in an electrolyte before applying the potential difference. Since the electrical energy is converted directly into chemical energy in an electrolytic process, the interaction between the chiral first surface (functioning as an electrode) and the electrolyte is configured for changing a spin state at an electrode-electrolyte interface and reduce the applied potential difference that was supposed to be applied whether the chiral system was not deposited on the electrode surface as will be exemplified further below with respect to FIG. 4B. Thus, when a second work function of the first surface carrying the chiral system is measured in 110, a change in the work function of the first surface is observed, such that Wf₂<Wf₁, i.e., the second work function is lower than the first work function.

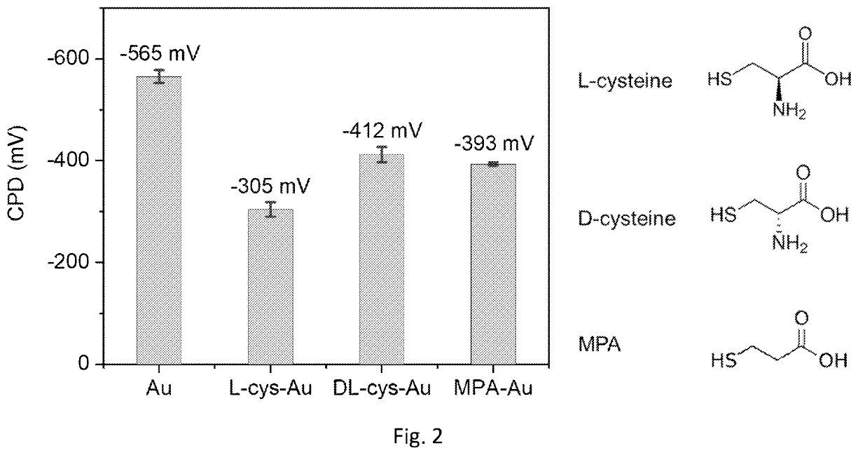

Reference is made to FIG. 2 showing the difference in the work function between a reference electrode measured by a Kelvin probe and a gold (Au) surface, either bare or coated with a monolayer of chiral molecule (e.g. cysteine) or with a monolayer containing the mixture of L and D enantiomers of cysteine, or a monolayer of achiral molecule 3-mercaptopropionic acid (MPA). More specifically, the work function of the bare gold surface was −565 mV, the work function of the gold surface coated with the monolayer of L-cysteine was −305 mV, the work function of the gold surface coated with the monolayer containing the mixture of L and D enantiomers of cysteine was −412 mV and the work function of the gold surface coated with the achiral molecules was −393 mV. In this connection, it should be noted that the achiral monolayer may change the work function of the electrode surface, but it increases the resistance of the electrode being thus less relevant for electrochemical applications. In the case of chiral molecules, due to the CISS effect, the resistance of the chiral film is low and the reduction in the work function compensates for the slight increase in resistivity. Therefore, it has been clearly shown that the presence of chiral molecules significantly reduces the work function of an electrode surface. The work function of the gold coated with the chiral monolayer is the smallest one (−305 mV).

The inventors found that when chiral material gets in contact with an electrode surface, charge rearrangement occurs in the chiral material. This charge rearrangement is accompanied by spin polarization. Hence the binding of the molecules with the substrate requires that the electrons of the substrate have an opposite spin relatively to the spin of the chiral material. The additional energy created by the charge rearrangement is proportional to the extent of spin polarization times the spin exchange interaction, in addition to the common chemical energy associated with the binding, stabilizing the binding.

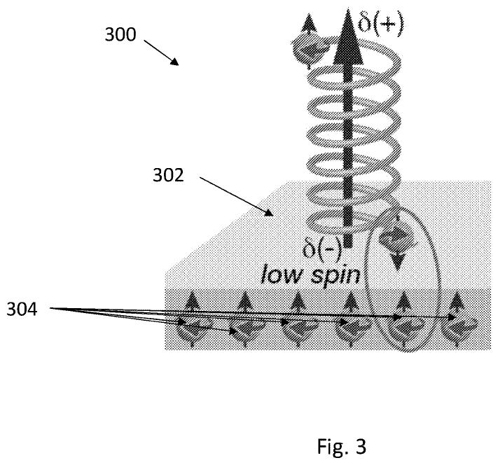

Reference is made to FIG. 3 showing an example of an electrode 300 for use in an electrochemical process of the present disclosure. When a chiral system 304 is carried by a substrate having an electrically conductive surface 302, the chiral system 304 is charged and spin polarized. Substrate 302 may be made of metal and/or semiconductors such as Pt, gold, silicon or Cu. In order to bind to the surface, the spins of the electrons on the surface 302 must be counter aligned to the spin of the electron that belongs to the molecules and is in proximity to the substrate. Hence the chiral layer 304 induces spin polarization in the outer most atoms. The electron injected from or to the surface 302 is therefore spin polarized so that it is transferred smoothly through the interface and the chiral molecule 304. In this way, chiral system 304 is configured for controlling the work function Wf of the electrode surface 302, such that the interaction between the chiral system 304 and the substrate 302 causes charge rearrangement, spin polarization of the surface 302 and spin polarization of electrons being injected from or to the surface 302. The stabilization energy due to the binding is the fraction of spin polarized electron times the spin exchange energy.

Reference is made to FIG. 4A showing an example of an electrochemical cell 400 using the electrode of the presently disclosed subject matter. Electrochemical cell 400 comprises an electrode 402 being made of a Zn substrate coated with chiral molecules and being immersed in an aqueous ZnSO₄ electrolyte. Electrochemical cell 400 also comprises a counter-electrode 404 being connected to the chiral electrode 402 via an electric module 406 being configured to apply a potential energy between the electrodes 402 and 404. Counter-electrode 404 is made of Cu and is configured to be immersed in an aqueous CuSO₄ electrolyte. The aqueous ZnSO₄ electrolyte and the aqueous CuSO₄ electrolyte are separated by a permeable (e.g. porous) membrane that prevents them from rapidly mixing but allows ions to diffuse through. The membrane may be a conventional membrane or may comprise a substrate having an electrically conductive surface at least partially carrying a chiral system. The excess electrons that remain when Zn²⁺ ions emerge from the Zn substrate in the left cell would be able to flow through the external circuit and into the right electrode, where they could be delivered to the Cu²⁺ ions which become “discharged”, that is, converted into Cu atoms at the surface of the copper electrode. The net reaction is the oxidation of zinc by copper (II) ions: The reaction can be started and stopped by connecting or disconnecting the two electrodes. By connecting a battery or other source of current to the two electrodes, we can force the reaction to proceed in its non-spontaneous, or reverse direction. The chiral molecules may be deposited on the Zinc electrode 402 as in the present example, but alternatively on the copper electrode 404, or on both. The presence of the chiral molecules on the Zn substrate enables to reduce the voltage applied to force the reaction to occur and to generate the electric current.

If electrochemical cell 400 is used as a source of electric power system (e.g., a Zn Cu battery) in which an electric current is generated from the spontaneous Oxidation-Reduction reactions, a large reduction of the potential barrier may be measured when the zinc electrode 402 (i.e., cathode) is covered with chiral coating, improving thus significantly the charging times. Typically, the source of electric power system comprises a plurality of electrochemical cells interconnected between them (in series and/or in parallel).

FIG. 4B is a diagram showing the potential over time of different configuration of electrochemical cells being indicative of the charging time and the potential barriers of the batteries having different configurations. The first curve 408A shows the measured potential when the anode and the cathode were coated with alpha-helix chiral molecules. In this connection, it should be noted that in some cases, coating the two electrodes may be of benefit for reducing the potential barrier and in other cases, like in this specific and non-limiting example, the coating of both electrodes may not reduce the potential barrier, depending on the specific relative potential of the two electrodes. The second curve 408B shows the measured potential when only the anode is coated with chiral molecules. The third curve 408C shows the measured potential when only the cathode is coated with chiral molecules, and the fourth curve 408D shows a control measurement with no molecular aggregates. It is clearly shown in the figure that the coating of the cathode with chiral coating generates a large reduction of the potential barrier for starting the electrochemical process indicated by an increase in the potential (from about 1.090V to about 1.094V) obtained in an electrochemical cell where the cathode is coated with chiral molecules compared to an electrochemical cell where the anode and the cathode were not coated.

In the following, the enhancement of Lithium-ion batteries' cathode performance by chiral molecular coating is described in detail.

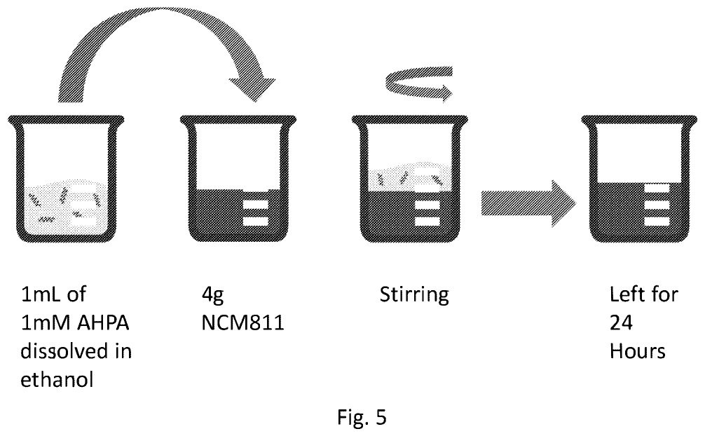

To study the effect of the CISS on Li-ion batteries the inventors adsorbed chiral AHPA molecules on the active material of the battery. The term “active material” refers hereinafter to the material being responsible for the reversible electrochemical reactions that occur during charge and discharge cycles. The active materials may be found in the positive and negative electrodes, or in the electrolyte. The active material can be an intrinsic chiral material, or a material being coated by chiral material(s). The electrolyte may be solid or liquid and may or may not have chiral properties. The flow processes for coating cathode materials with chiral molecules are illustrated in FIG. 5. Cathode powders of commercial LiNi_{0.8}Mn_{0.1}Co_{0.1}O₂ (NMC 811) bought from TARGRAY-USA are UV treated before inserted into an L-Alpha-Helix-Polyalanine (AHPA), 3008.71 g/mol 1 mM ethanol solution. A total amount of 3 mg of APHA was used to coat 4 g of NMC811 powder. The reactor is gently shaken to homogenize the suspension during the coating process. After 24 hours of drying the sample under nitrogen environment a coated NMC811 powder is obtained (Chiral-A). In Chiral-B sample, the same concentration of 1 mM was used for the coated NMC811 however the sample was not left in the solution to dry but was washed by the chiral solution using a 2 μm filter paper (Chiral-B). A control sample was prepared in the same manner as the Chiral-A process but with achiral molecules (12-mercaptododecanoic acid Sigma Aldrich, 232.38 g/mol) (Achiral-C). The proposed procedure is extremely simple and can be easily scaled up for battery production.

The crystal structures of samples were determined using X-Ray Diffraction (XRD, D8 advance, Bruker). The chemical compositions of the coating layers with cathode materials were analyzed by X-ray Photoelectron Spectroscopy (XPS, Thermo Scientific K-Alpha) under Al Kα radiation. The X-ray Photoelectron Spectroscopy (XPS) measurements were performed in UHV (2.5×10⁻¹⁰ Torr base pressure) using the 5600 Multi-Technique System (PHI, USA). The samples were irradiated with an Al Kα monochromatic source (1486.6 eV) and the outcoming electrons were analyzed by a spherical capacitor analyzer using the slit aperture of 0.8 mm. The morphology of the samples was analyzed using high-resolution scanning electron microscopy (HRSEM) FEI, Magellan 400Lis. The morphologies and microstructures of samples were detected by field emission scanning electron microscope (Nova Nano SEM 450, FEI) and high-resolution transmission electron microscopy (HRTEM, Tecnai G2 F20, FEI).

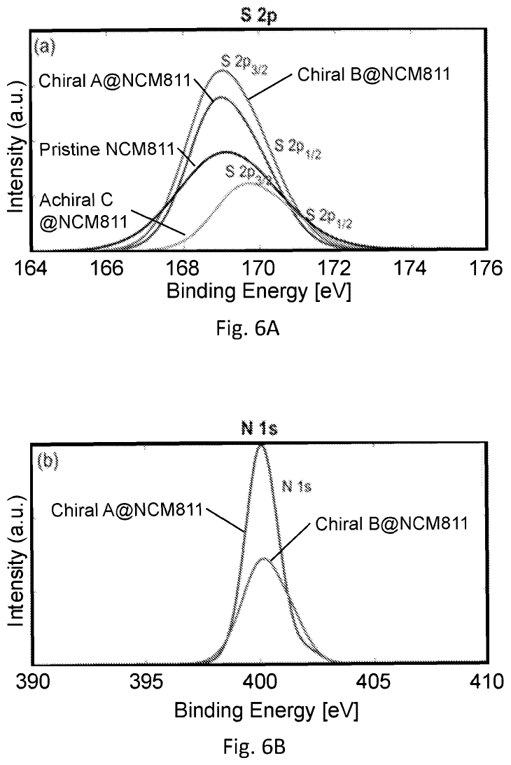

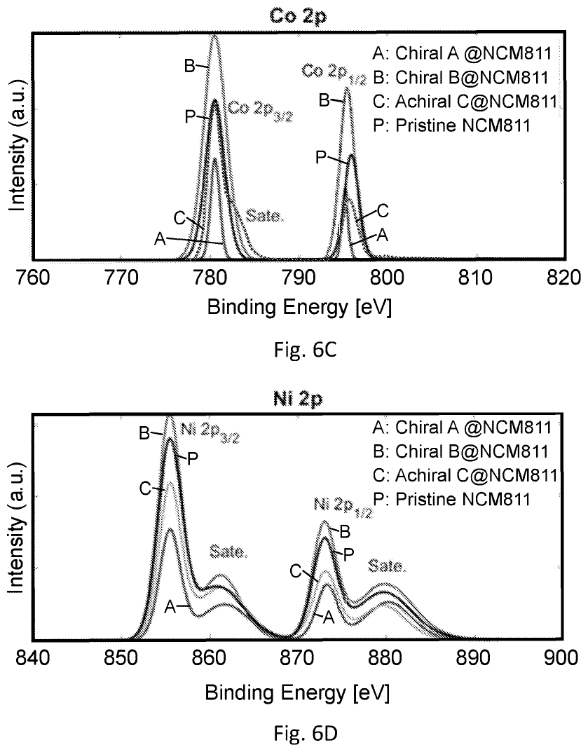

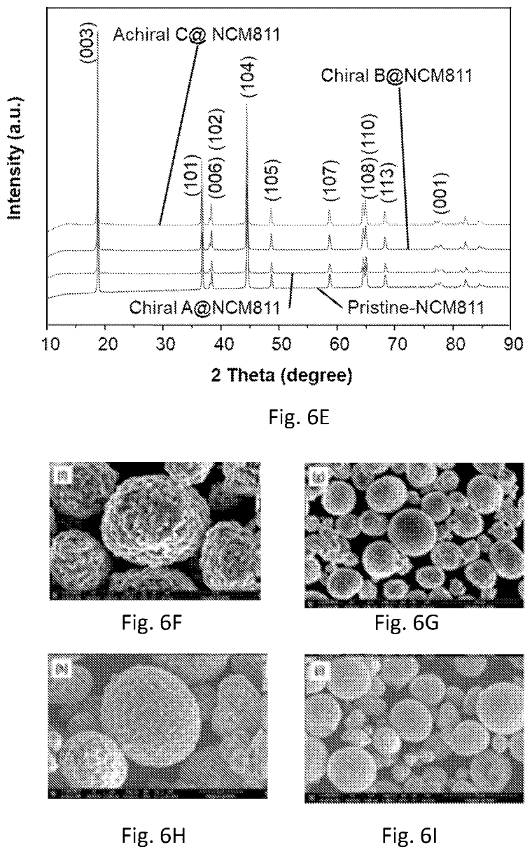

FIGS. 6A to 6D show XPS spectrum of the samples chiral-A, Chiral-B, Achiral-C, and Pristine NCM811. The results imply that the organic material was adsorbed on the NCM particles. FIG. 6A shows the existence of organic material in the treated samples indicated by the 2S peak. FIG. 6B presents the typical XPS spectrum of N Is, in which a peak at 400.1 eV associated with pyrrolic N is observed and can be related to amino groups in the chiral polypeptides. In the high-resolution XPS spectrum of Ni 2p (FIG. 6C), apart from two satellite peaks at 879.6 and 861.5 eV, the other two peaks at 873.5 and 855.9 eV are ascribed to Ni 2p_{1/2} and Ni 2p_{3/2}, respectively. In addition, FIG. 6D displays two significant peaks at 796.6 and 780.9 eV assigned to Co 2p_{1/2} and Co 2p_{3/2}, indicating the existence of Co²⁺ and Co³⁺ in all samples of Chiral-A, Chiral-B, Achiral-C and Pristine-NCM811 [59]. The Ni and Co transition metals (TMs) in the uncoated NMC particles are higher by three folds as compared to the coated sample, as expected due to the coatings, given the nominal calculated length of AHPA is 5.4 nm and the achiral is 2.6 nm [60]. No shift has been obtained by comparing the binding energy values for the pristine and chiral-coated NMC811 cathodes (Table 2 below). The XPS analysis indicates that chiral coating on the NMC811 cathode does not change the interfacial composition or oxidation states of the NMC811 core.

FIG. 6E displays XRD diffraction peaks of the NCM powder samples in the 20 range of 10°-80°. All diffraction peaks are well indexed with respective crystal planes of the hexagonal crystal structure with a space group of R-3m. Adsorption of chiral molecules does not change the NCM properties, and neither do achiral molecules, as seen from the diffraction. The XRD patterns of the as-prepared powders, from which the layered structure with highly crystalline can be observed for all four samples. All the diffraction peaks are indexed to the hexagonal α-NaFeO₂ structure with space groups, and there is no obvious change in the XRD patterns of coated samples and pristine NCM which has denoted the similar crystal structure of cathode materials before and after surface modification. The results also indicate that no impurities exist in the NCM powder samples, suggesting the small content and the amorphous state of the Chiral molecule: L-alpha helix Polyalanine (AHPA) and the Achiral molecule: 12-mercaptododecanoic acid (MDA) on the surface of NCM particles owing to the nature of thin coating which has not detected by XRD [61]. Normally, the intensity ratio of (003) and (104) diffraction peaks can be used to determine the order of cations in NCM materials, and the ratio value is inversely proportional to the cationic order. The layered structure with a lower degree of cation mixing is more stable when the ratio >1.2. After calculation, the I (003)/I (104) ratio for the four samples Chiral-A, Chiral-B, Achiral-C, and Pristine NCM811 are 1.35, 1.46, 1.35 and 1.58, respectively. In addition, the splitting double peaks of (006)/(102) and (108)/(110) represent the order degree of material crystal structure which has not been affected with the chiral protected cathode materials. Both results confirm well that the materials have a layered structure. In summary, it is concluded that the NCM samples with layered structure can be successfully retained after the chiral protective coating on the pristine NCM811.

The electron microscopy (HRSEM) images of Chiral-A, and Pristine NMC811 are presented in FIGS. 6F to 6I. FIGS. 6F-6G show, respectively, high and low magnification images of sample Chiral-A, and FIGS. 6H-6I show, respectively, high and low magnification images of sample Pristine NCM811; The HRSEM images show that the chiral and achiral coating on NMC811 particles was not affected or degraded by the adsorption process and the particles' spherical structures were preserved. The elemental maps of the individual particles demonstrate that the coating is uniform around the particle surface. The results are summarized in Table 1 below:

TABLE 1
XPS Intensities (A.U)

| | S 2p_{1/2} | N 2s | Co 2p_{1/2} | Co 2p_{3/2} | Ni 2p_{1/2} | Ni 2p_{3/2} |
|---|---|---|---|---|---|---|
| Chiral-A | 163 | 2982 | 192 | 268 | 770 | 1543 |
| Chiral-B | 138 | 1431 | 453 | 592 | 1645 | 3153 |
| Achiral-C | 61 | 0 | 158 | 413 | 955 | 2198 |
| Pristine | 89 | 0 | 276 | 420 | 1417 | 281 |
| NCM811 | | | | | | |

Electrochemical tests were carried out by using the 2032 coin-type test cells. The cathode composed of polyvinylidene fluoride (PVDF) binder (10 wt %), acetylene carbon black (10 wt %), and Chiral-coated NCM811 active material (80 wt %) was dispersed into N-methylpyrrolidone (NMP) to make a homogeneous slurry. The slurry was cast onto an aluminum foil and dried on a hotplate followed by drying at 110° C. under a vacuum overnight to evaporate the NMP solvent. The dried cathode was cut into a circle with a diameter of 12 mm as the cathode electrode of the LIB coin-cells, and the mass loading of active materials was ≈2.34 mg. Lithium foil (200 μm thick) and Celgard pp 2500 polypropylene membrane served as anode and separator, respectively. Commercial Electrolyte solution LP-57 comprising 1M LiPF6 in ethylene carbonate-ethyl-methyl carbonate mixture (3:7; v: v) was used as the electrolyte. The assembly of the coin-cells (CR-2032) was implemented in a glove box filled with argon gas, and the moisture and oxygen content was ≤0.1 ppm. The cycle and rate performance were galvanostatically performed within the voltage window of 2.8-4.3 V and 2.8-4.5 V (vs. Li/Li+) using a Neware battery tester at room temperature (30° C.), respectively. The cyclic voltammetry (CV) with a potential scan rate of 0.1 mV s⁻¹ within 2.8-4.5 V, and the electrochemical impedance spectroscopy (EIS) tests within a frequency range of 0.01-10⁵ Hz at a perturbation amplitude voltage of 5 mV were carried out on Biologic (VSP) system.

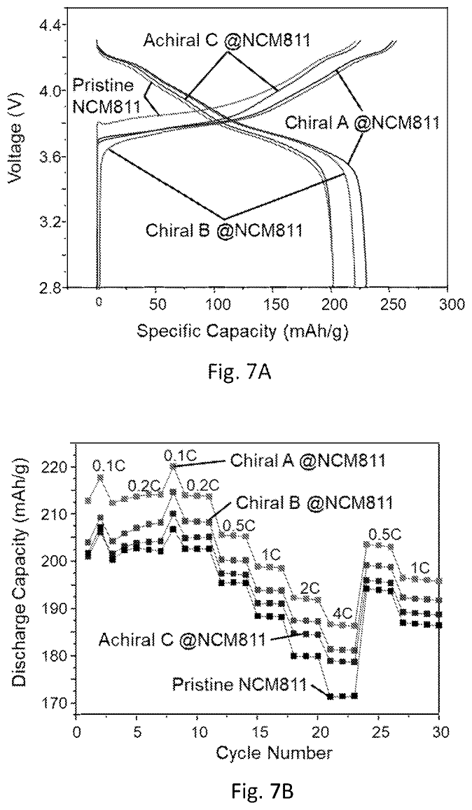

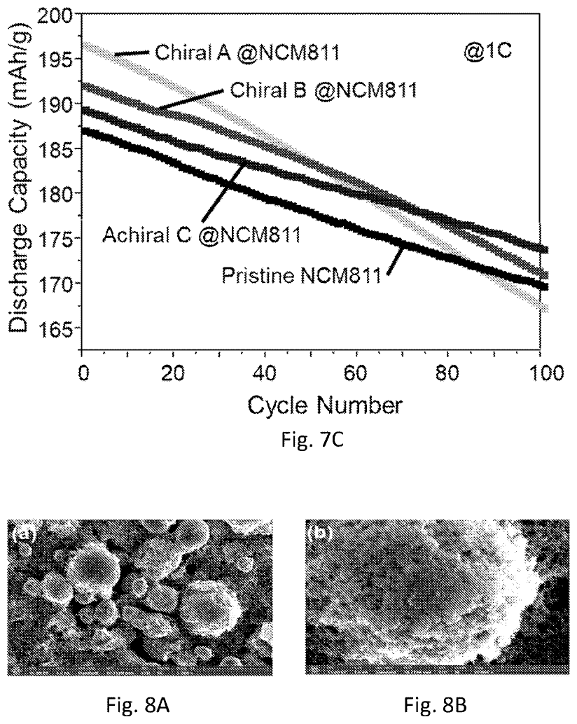

The I-V profiles for uncoated NMC811 (pristine) and coated NMC811 electrodes (versus Li counter electrode) are presented in FIG. 7A. Both uncoated and coated NMC811 samples exhibit two voltage plateaus at ~3.7 V and ~4.2 V. The overlapped voltage profiles in FIG. 7A show two main observations. First, a lower average overpotential obtained by the chiral coated NMC811 with respect to the achiral coated or uncoated NCM811. Secondly, cells with chiral coated NMC present a higher specific discharge capacity than the achiral coated or uncoated NMC.

The performance of the samples was evaluated in the voltage range from 2.8 to 4.3 V using coin-type CR2032 lithium half cells at rates ranging from 0.1C (discharge at 10 hours) to 4C (discharge at 15 minutes). The initial charge-discharge formation voltage profile of all four samples at 0.1C rate is shown in FIG. 7A. The specific discharge capacities for Chiral-A, Chiral-B, Achiral-C, and Pristine NMC cathodes are 217.7+−1, 209, 207, 206 mAh/g, respectively. As can be seen, the rate performance is improved by the surface coating. At low C-rates (0.1 and 0.2 C), the chiral-A sample NMC811 delivered larger specific discharge capacities (5-10 mAh/g) than the other samples.

A more significant enhancement in discharge capacity was observed at higher rates of 1, 2, and 4C. Compared to the pristine sample, the specific discharge capacities of the Chiral-A sample show an average of 8.7% increase in the specific discharge capacities at 4C and a 6%+−0.2 on average. Samples Chiral-B and Achiral-C show smaller increase in the specific discharge capacities of 5.7% and 4.6% at 4C and 3% and 1.8% on average, respectively. These results demonstrate that coating the NMC811, in general, improves the kinetics of the Li intercalation/deintercalation processes as both chiral and achiral coatings increase performance. This implies that the organic coatings can prevent electrolyte solution breakdown on the NMC surface, forming a thick passivation layer that slows Li intercalation/deintercalation kinetics. However, the cells with the chiral coating outperform those with achiral coatings. This demonstrates that, besides physical protection, the chiral coating improves the discharge/charge processes.

Overall, the electrochemical performance of all three protected NMC cathode materials Chiral-A, Chiral-B, and Achiral-C show better rate capabilities than pristine-NCM811. The chiral coating improvement in the charge-discharge processes leads to stable configuration and lower electric resistivity in the cell. The lower the electric resistivity in a coin cell, the lower the implied voltage for a given discharging rate, which brings us to a more stable voltage discharge regime. Compared with the pristine-NCM811 cathode, the electrochemical performance in terms of discharge specific capacity is enhanced in all three molecular protected NCM811 cathodes samples Chiral-A, Chiral-B, and Achiral-C. Upon cycling all samples (coated and uncoated) undergone a reasonable capacity decay. The discharge capacity retention of samples Chiral-A, Chiral-B, and Achiral-C are 84.5%, 89%, and 92% after 100 cycles at 1C rate, respectively. The pristine NMC811 uncoated sample attained the discharge capacity retention at 91%. The long-term stabilization of the NMC811 interface using chiral or achiral coatings is not observed. These results indicate that the protective coating layer inhibits the direct contact between the electrolyte and NCM811 particles which stabilize the electrochemical reaction of the interface and SEI interface layer. The thickness of the coating has a great influence on the electrochemical performance of the cathode materials. Thin coating layers (1-3 nm) are not enough to protect NCM811 and its ability to hinder the side reactions at the interface is poor as observed here for the Chiral-B and Achiral-C samples. Thicker coating layer (about 10 nm) increases the stability and performance as shown for the Chiral-A sample, which causes the diffusion path of Li⁺ through the chiral molecular protection layer to be longer and hinders the transfer of Li⁺.

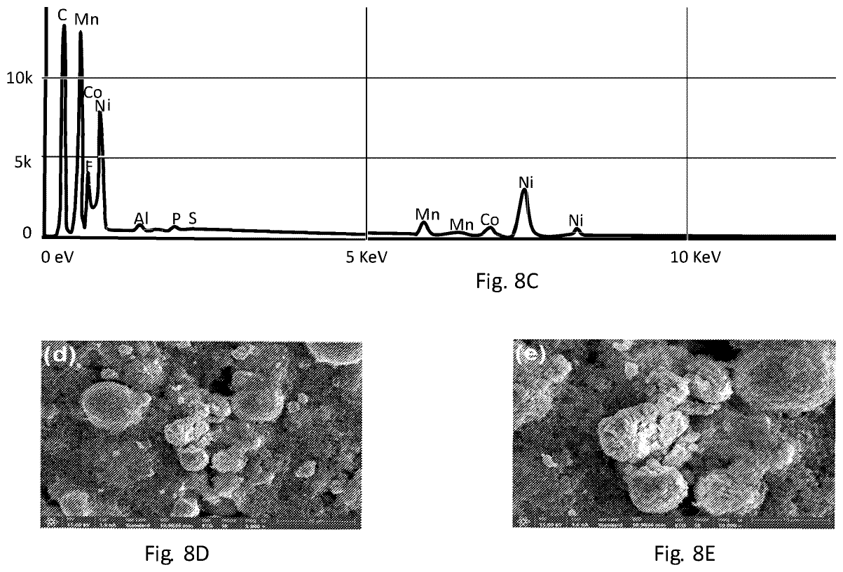

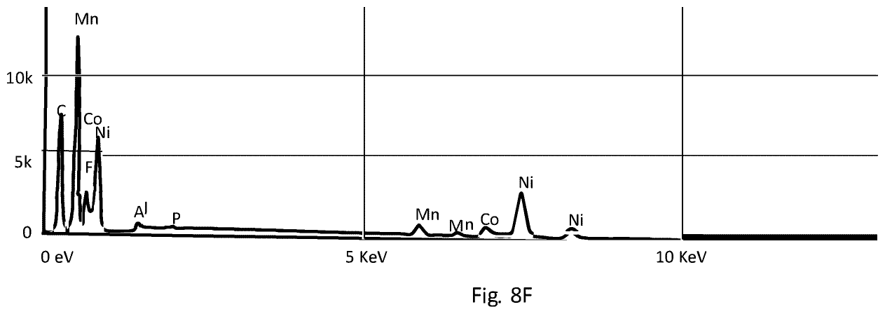

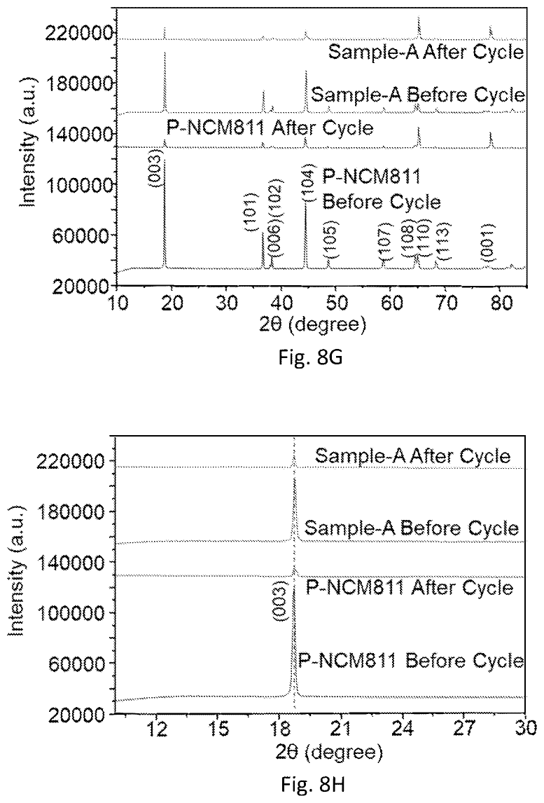

Lastly, the morphology and composition of the cathode materials were further investigated by using high-resolution scanning electron microscopy (HR-SEM) and EDX spectroscopy after cycling the electrodes which are shown in FIGS. 8A to 8F. The treated sample Chiral-A electrode does not have the crack and structural degradation on the core NCM 811 particles after continuous electrochemical charge-discharge cycling. In the case of the pristine samples, a clear degradation of primary particles from the secondary macro-sized particles is observed with few cracks' formation and erosion. The EDX spectra of sample Chiral-A (FIG. 8C) and Pristine NCM811 (FIG. 8F) cathodes confirm the retention of NCM811 composition after the continuous charge-discharge cycling of the cathode. Therefore, the inventors found that the decay is similar in all cases considering that longer cycles were obtained with higher capacity. The X-ray diffraction pattern shown in FIGS. 8G and 8H of the chiral protective coated Chiral-A and the Pristine NCM811 electrodes shows that there is no structural and phase change after continuous cycling.

Thus, the inventors demonstrated that using a chiral coating technique to modify the surface of NMC811 materials can significantly improve the electrochemical performance of lithium-ion cells. The NMC811 electrodes coated with chiral molecules exhibited lower voltage hysteresis and better rate performance, with a capacity improvement of 9% at a 4C discharge rate and an average improvement of 6% in rate capability measurements. On the other hand, achiral samples showed a capacity improvement of only 4.6% at 4C and an average improvement of 2%. These results demonstrate that the chiral-induced spin selectivity (CISS) effect plays a vital role in the charge/discharge process. The capacity retention rate for Chiral treated cells was only 85% after 100 cycles compared to Achiral treated cells with 92% and pristine cells with 91%.

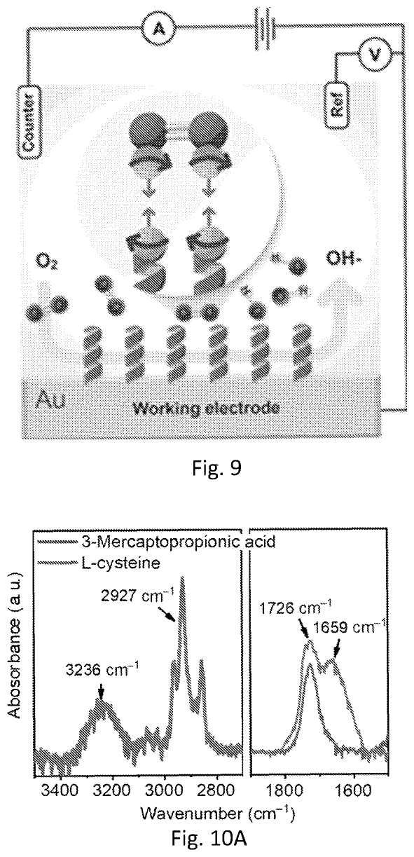

Reference is made to FIG. 9 showing a schematic layout of the electrochemical setup, which includes a gold working electrode coated with a self-assembled monolayer (SAM) of either chiral or achiral molecules. The inventors used an electrochemical assay in which O₂ was bubbled into an electrochemical cell and the reductive current was monitored. The electrochemical cell was assembled with a Pt counter electrode, an Ag/AgCl reference electrode, and a working electrode that could be either chiral or achiral. In the first stage of the work, the inventors utilized a 100 nm thick gold film that was coated with a self-assembled monolayer (SAM) of chiral cysteine and oligopeptides, SH—(CH₂)₂—NH-(Ala-Aib)ₙ-COOH (n=3, 5, 7, 8, 11 referred to as L-ala3, L-ala5, L-ala7, L-ala8, and L-ala11, respectively), or with a monolayer of achiral molecules, 3-mercaptopropionic acid and SH—(CH₂)ₙ—CH₃ (n=3, 7, 9, 13, 17) as shown in Table 2 below).

TABLE 2

| Samples | | Chemical formula |
|---|---|---|
| Chiral | L-cysteine | SH—CH₂CH(NH₂)—COOH |
| | L-ala3 | SH—(CH₂)₂CO-(Ala-Aib)₃-COOH |
| | L-ala5 | SH—(CH₂)₂CO-(Ala-Aib)₅-COOH |
| | L-ala7 | SH—(CH₂)₂CO-(Ala-Aib)₇-COOH |
| | L-ala8 | SH—(CH₂)₂CO-(Ala-Aib)₈-COOH |
| | L-ala11 | SH—(CH₂)₂CO-(Ala-Aib)₁₁-COOH |
| Achiral | 3-Mercaptopropionic | SH—(CH₂)₂—COOH |
| | acid | |
| | 1-Butanethiol | SH—(CH₂)₃—CH₃ |
| | 1-Octanethiol | SH—(CH₂)₇—CH₃ |
| | 1-Decanethiol | SH—(CH₂)₉—CH₃ |
| | 1-Tetradecanethiol | SH—(CH₂)₁₃—CH₃ |
| | 1-Octadecanethiol | SH—(CH₂)₁₇—CH₃ |

The solutions used to prepare the monolayer were first bubbled with Ar for more than 30 min. The achiral alkanethiol molecules were dissolved in ethanol to form a 1 mM solution. The chiral oligopeptides were dissolved in 2,2,2-trifluoroethanol (≥99%, Sigma-Aldrich) to form a transparent solution of 1 mM. The Au film electrodes were prepared by e-beam evaporation on single-crystal silicon wafers with a combination of Cr (10 nm)/Au (100 nm) layers. Prior to adsorption, the surfaces were cleaned by boiling in acetone and in ethanol for 10 min each, followed by UV/ozone treatment for 15 min, and then immersing in ethanol for 40 min. These surfaces were then dried under nitrogen gas flow and immediately immersed in the solution of thiol molecules for 72 h.

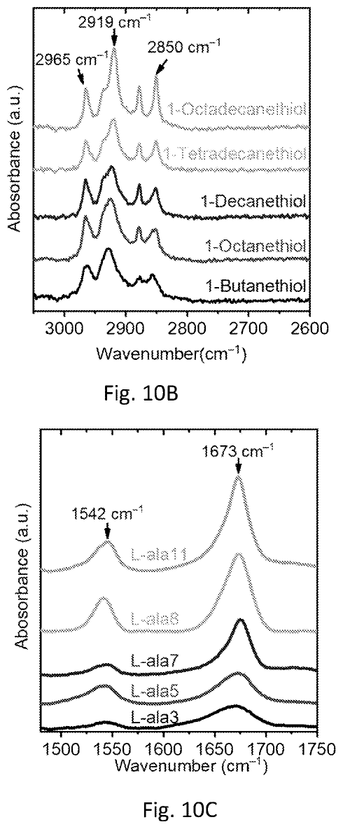

The monolayer formation was characterized by infrared spectroscopy, using a polarization modulation-infrared reflectance-absorption spectrometer (PM-IRRAS) and the respective spectra are shown in FIGS. 10A-10C. The spectra were recorded using a Nicolet 6700 FTIR instrument equipped with a PEM-90 photo-elastic modulator (Hinds Instruments, Hillsboro, OR). Each spectrum was obtained by accumulating 2000 scans with the samples mounted at Brewster angle of 80°. The spectra of the 3-mercaptopropionic acid (MPA) and L-cysteine monolayers (FIG. 10A) show characteristic peaks at 3236 cm⁻¹ due to the stretching mode of OH of carboxylic group. The strong peaks that belong to the asymmetric and symmetric C—H stretching frequency of the —CH₂ group at 2927 cm⁻¹ were also observed. There is also a signature of carbonyl (C═O) stretching mode of the carboxylic group at 1726 cm⁻¹. Note that L-cysteine monolayer shows a weak vibrational band at 1569 cm⁻¹, which is attributed to the N—H bending in NH₂ group. On the contrary, the inventors did not observe this peak for 3-mercaptopropionic acid monolayer (FIG. 10A), which is consistent with their molecular structures (Table 1 above). Apart from the N—H vibration of NH₂ group, the intensity of other peaks for both L-cysteine and MPA are almost the same, indicating a similar coverage of these surfaces.

For the alkanethiol coated Au surfaces, the strong peaks in the range from 2851 cm⁻¹ to 2965 cm⁻¹ are assigned to the asymmetric and symmetric C—H stretching frequency of the —CH₂ group present in the alkyl chain (FIG. 10B). In addition, the peak intensities increase from 1-butanethiol to 1-octadecanethiol in accord with the increasing length of the alkyl chain.

FIG. 10C shows the PM-IRRAS spectra of the oligopeptide monolayers. The strong peak at 1673 cm⁻¹ is the typical stretching mode of the CO bond (amide-I), while the peak at 1542 cm⁻¹ can be attributed to the N—H in-plane bending mode and C—N stretching mode (amide-II). Moreover, the intensities of these two characteristic peaks increase with the length of oligopeptides, demonstrating that the Au surface was successfully coated with the different chiral molecules.

Electrochemical measurements were performed using a three-electrode electrochemical cell, equipped with an Ag/AgCl reference electrode and a platinum wire as the counter electrode. The working electrode was an Au film modified with different molecules (vide supra). Electrochemical data were recorded at room temperature on a potentiostat (PalmSens4) electrochemical workstation. The potential was measured versus an Ag/AgCl (3M NaCl) reference electrode, and then calibrated with reference to a standard reversible hydrogen electrode (RHE). The working electrode was static during all the measurements.

The electrochemical reduction was performed at pH=13 with 0.1 M KOH in aqueous solution. Oxygen was bubbled for at least 30 min before starting the measurements, to ensure saturation. All applied potentials were converted to the standard reversible hydrogen electrode (RHE) reference scale.

Under the alkaline conditions of these studies, two reduction pathways are commonly considered to be possible [62]:

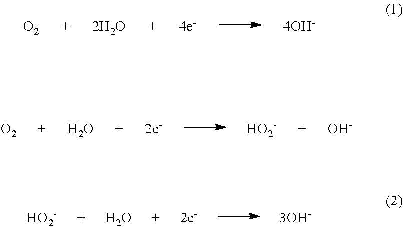

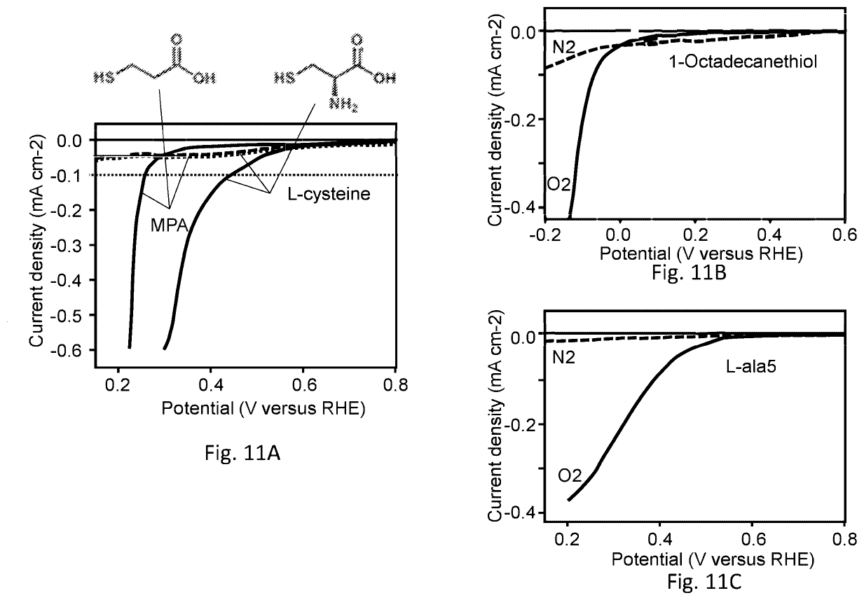

FIGS. 11A-11C show oxygen reduction activity of molecules-coated electrodes. FIG. 11A presents current versus voltage plots for electrodes that are coated with a SAM of achiral 3-mercaptopropionic acid (blue) or with chiral L-cysteine (red) in N₂ (dotted curves) and O₂ (solid curves)-saturated 0.1 M KOH solution. The onset potential is defined as the potential at which the current reaches a value of 0.1 mA/cm², as noted by the dashed line. Current densities were normalized in reference to the geometric area of the working electrode. FIGS. 11B and 11C show the current versus potential measured when the electrode is coated with a monolayer of achiral molecules (1-octadecanethiol) (FIG. 11B), and chiral oligopeptides (L-ala5) (FIG. 11C) in N₂ (dotted curves) and O₂ (solid curves)-saturated 0.1 M KOH solution.

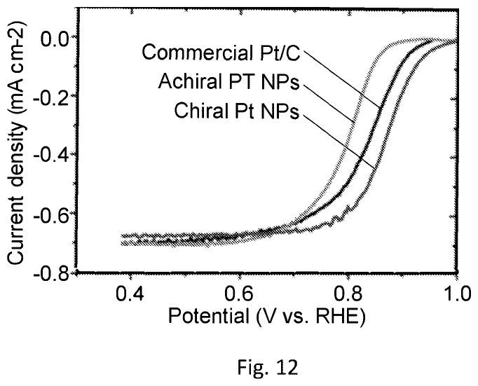

The significant difference of current density in O₂ and N₂ saturated solutions indicates that both chiral- and achiral-functionalized electrodes show activity for oxygen reduction. Despite the two molecules being of the same length and of very similar structure (FIG. 11A), a shift of about 0.25 V in the onset potential for the reduction is clearly evident. It should be noted that a more positive potential implies a lower barrier for the ORR and that the coverage of organic molecules on the Au surface leads to onset potentials that are smaller than that found for the bare Au, with reference to FIG. 12 [63].

FIG. 12 shows current versus potential for three electrodes, commercial Pt/C, achiral Pt NPs and chiral Pt NPs electrodes. The current versus potential measured with bare commercial Pt/C, achiral Pt NPs and chiral Pt NPs at a scan rate of 50 mV/s. It is clearly shown in the figure that the coating of the electrode with chiral coating generates a reduction of the potential barrier for starting the electrochemical process indicated by an increase in the potential. The electrodes being made by using the teachings of the novel technique of the present disclosure are thus capable of reducing the electrodes' over potential and enhancing charge separation efficiency while decreasing recombination loss.

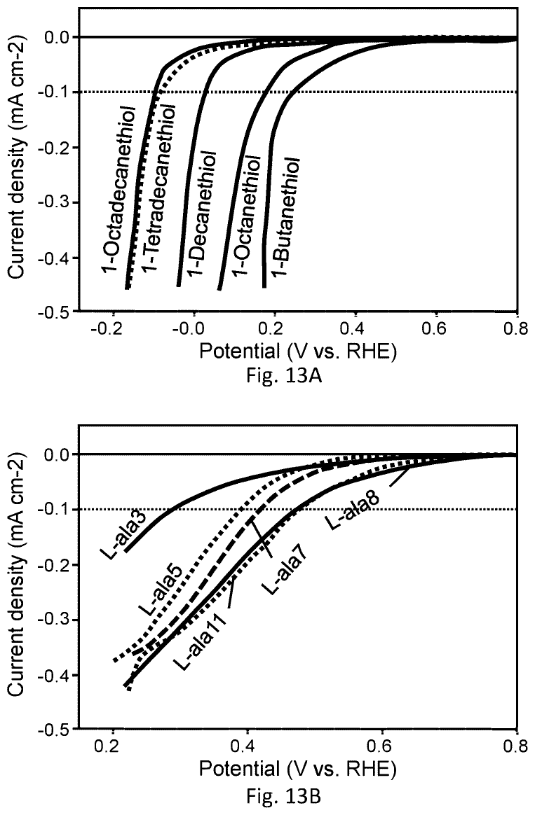

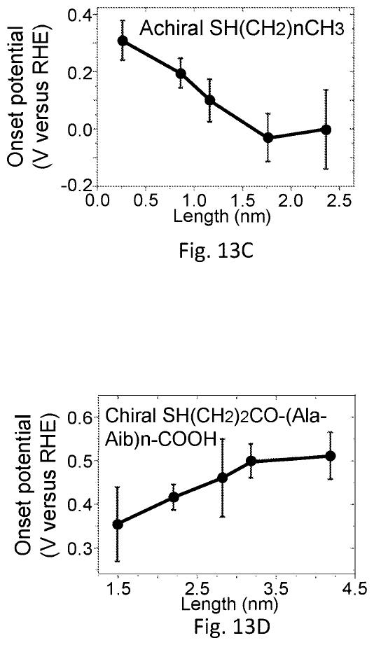

FIGS. 13A and 13B show the current vs. voltage curves for the ORR when the electrode is coated with achiral (FIG. 13A) and chiral molecules (FIG. 13B) of different lengths. As seen in FIG. 13C, the onset potential decreases with increasing molecular length for the achiral molecules, indicating an increase in the reaction barrier with increasing SAM thickness. In stark contrast, the onset potential increases with increasing molecular length for the chiral molecules (FIG. 13D), indicating a decrease in the reaction barrier with increasing SAM thickness. The higher barrier that is observed for the achiral molecules is consistent with the increase in electrical resistance of the molecules with increasing length and the decrease in O₂ solubility with the increasing molecular length of alkanes. The inventors examined whether a lower potential (higher overpotential) is required to achieve the same current density for a thick film as that observed for a thin film. Surprisingly though, for the SAMs comprising chiral molecules, the potential increases with the length, even though the molecules resistance is known to increase with length, and the diffusion of O₂ through the layer to the electrode is expected to decrease with the molecular length. The unusual decrease of the ORR reaction barrier with increasing oligopeptide length correlates with the improved spin filtering of oligopeptides with increasing length (vide infra).

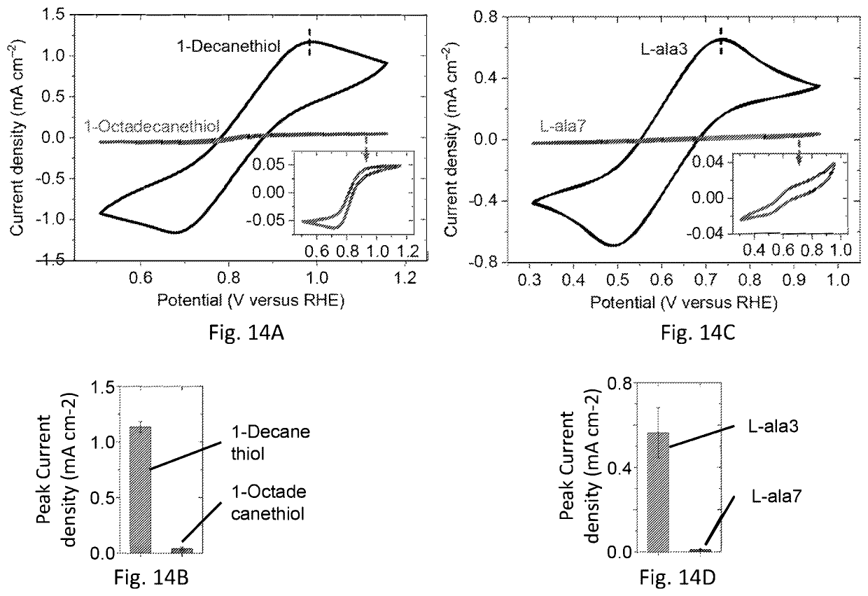

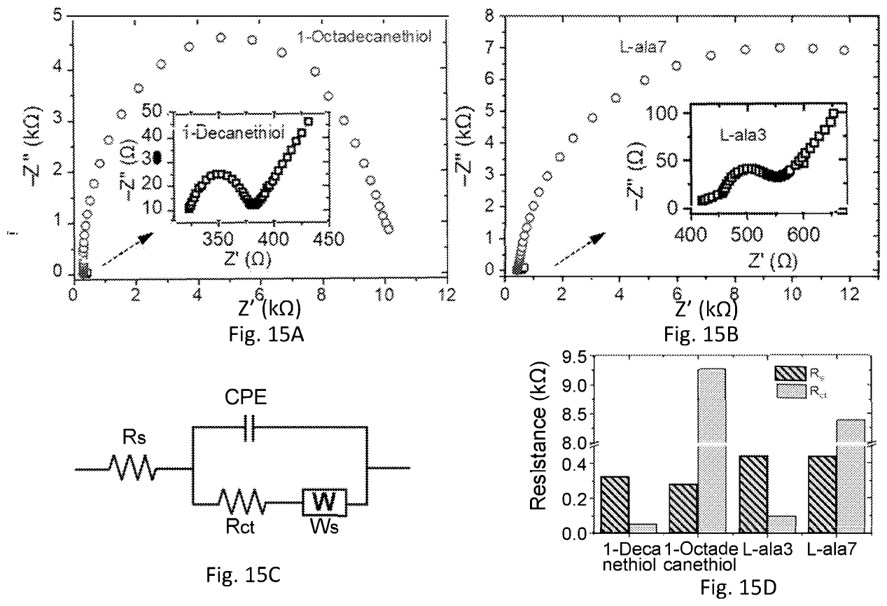

To confirm that the different behavior does not arise from significant length differences or SAM qualities between the two types of molecules, the current vs potential curves were measured for the ferri/ferrocyanide (Fe(CN)₆^{3-/4-}, 10 mM) redox couple in 0.1 M KCl aqueous electrolyte solution, instead of oxygen, hence the redox couple in the solution is not sensitive to the molecules being chiral or achiral. Cyclic voltammetry (FIGS. 14A-14D) and electrochemical impedance spectra (FIGS. 15A-15D) were collected in aqueous solution with 0.1 M KCl and 10 mM Fe(CN)₆^{3-/4-}. Electrochemical impedance spectra were conducted with a frequency range of 50 kHz-5 Hz.

FIGS. 14A-14D describe resistance characterization of the chemically coated electrodes. The cyclic voltammetry curves obtained for the electrode coated with either achiral (FIG. 14A) or chiral (FIG. 14C) monolayers. The curves are presented for short (1-Decanthiol (FIG. 14A) and L-ala3 (FIG. 14C)) and long (1-Octadecanthiol (FIG. 14A) and L-ala7 (FIG. 14C)) molecules; the insets show the curves for the long molecules in which the current axis is magnified. The dashed lines (in FIGS. 14A and 14C) indicate the voltage at which the peak current density was obtained. In panels shown in FIGS. 14B and 14D, the peak currents of the long and short molecules are presented for the achiral (FIG. 14B) and chiral (FIG. 14D) molecules, respectively. It should be noted that the ratios between the peak currents are very similar for the two types of molecules.

Given that the achiral ferricyanide is a low spin d⁵ complex and ferrocyanide is a low spin de coordination complex, no effect from spin polarization is expected for electron exchange with this redox couple. In this case, the surfaces coated with shorter molecules (1-Decanethiol in FIG. 14A and L-ala3 in FIG. 14C) show a much higher redox peak current than that of longer molecules (1-Octadecanethiol in FIG. 14A and L-ala7 in FIG. 14C), independent of whether the molecules are chiral or achiral.

These findings are corroborated by impedance measurements which show that the impedance increases with length for both types of molecules, as shown in Table 3 below and FIGS. 15A to 15D.

TABLE 3

| | | Peak current | Charge transfer |
|---|---|---|---|
| Samples | | density (mA/cm²) | resistance (Ω) |
| Achiral | 1-Decanethiol | 1.14 ± 0.05 | 52.7 |
| | 1-Octadecanethiol | 0.04 ± 0.01 | 9260 |
| Chiral | L-ala3 | 0.56 ± 0.12 | 97.0 |
| | L-ala7 | 0.01 ± 0.003 | 8390 |

FIGS. 15A and 15B show electrochemical impedance spectra of (FIG. 15A) achiral (1-decanethiol, 1-octadecanethiol) and (FIG. 15B) chiral molecules (L-ala3, L-ala7) coated surfaces within a three-electrode system. FIG. 15C shows an equivalent circuit model employed to fit the electrochemical impedance spectra. Rₛ is the sum of the electrode and electrolyte resistance, CPE is the double layer capacity, R_{ct} represents the charge transfer resistance, and Wₛ stands for Warburg impedance within the diffusion component; FIG. 15D is a summary of the Rₛ and R_{ct} values estimated from the equivalent circuit model. From the Nyquist curves (FIG. 15A), a much smaller semicircle of 1-decanethiol is observed than that of 1-octadecanethiol, indicating a more efficient charge transfer process at electrodes coated with short molecules. In FIG. 15D, it can be seen that the calculated Rₛ for 1-decanethiol and 1-octadecanethiol systems are nearly the same, while the R_{ct} values significantly decreased with the molecular length. Similar results were observed for chiral L-ala3 and L-ala7 (FIGS. 15B and 15D).

The inventors further examined whether the chiral enhancement takes place also when the electrode is made with materials with inherently large spin orbit coupling. The inventors produced chiral thin Au films through electrodeposition, in the presence of tartrate ions in the deposition solution using the following procedure. Briefly, 0.2 M L- or DL-tartaric acid, 0.02 M Na₃Au(S₂O₃)₂, 0.42 M Na₂S₂O₃, 0.42 M Na₂SO₃ were added in 10 mL of water and the pH was adjusted to 8. A three-electrode electrochemical cell was employed for the deposition in which a 15 nm of Au coated quartz substrate was used as the working electrode. A saturated calomel electrode (SCE) and a Pt wire were used as the reference and counter electrode, respectively. For the deposition, a constant potential of −0.63 V was applied for 5 minutes. After the electrodeposition, the electrode was washed with water and used for the ORR experiment.

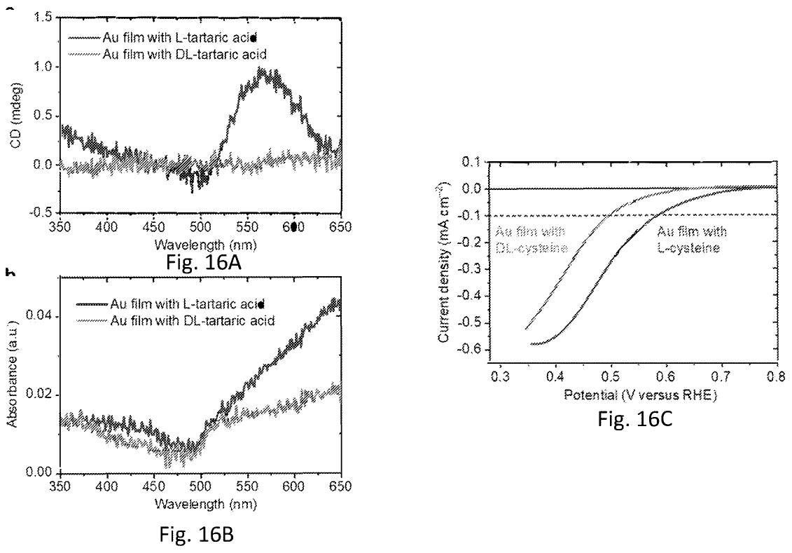

The handedness of the deposited chiral Au film was determined by the chiral tartrate ions. The Circular Dichroism (CD) measurements were carried out using a Chirascan spectrometer, Applied Photo Physics, England. The measurement conditions for all spectra were done at a scan range of 185 to 700 nm; 0.5 sec time per point; 1 nm step size; and a 1 nm bandwidth. For the solution sample, a quartz cuvette with an optical pathway of 2 mm was used. The CD spectra of Au films with L or DL-tartaric acid were measured on quartz substrate with a thickness of 0.5 mm and are shown in FIG. 16A. FIG. 16B shows the UV-visible absorption spectra of the synthesized gold (Au) films with L- or DL-tartaric acid.

The synthesized chiral Au thin films on quartz substrates were directly used as the working electrode for oxygen reduction reaction. For the Au and Pt NPs, the same amount of chiral or achiral NPs was dispersed in water by vigorous stirring and sonication. 8 μL of the NPs solution was dropped onto a glassy carbon electrode (GCE; 3 mm in diameter from ALS Co., Ltd., Japan). The loading amount of metal Pt were kept as 42 μg per cm² geometric area (confirmed by ICP-MS). After water evaporation under room temperature for 3 h, 4 μL of 0.05 wt % Nafion solution was dropped on the electrode surface to cover and stabilize the NP assembly on the electrode surface. Such NPs loaded GCE was immersed into the solution as a working electrode. ORR activities were measured under oxygen purging in O₂-saturated 0.1 M KOH at room temperature at a sweep rate of 50 mV/s.

The onset potential obtained with the ‘chiral gold film’ was improved compared with that of chiral monolayer coated Au electrodes as shown in FIG. 16C (compared with FIG. 3A). Moreover, the ORR onset potential of the chiral metallic Au film was 90 mV higher than that of the film made with a racemic mixture of tartaric acid (onset potentials at −0.1 mA/cm² are 0.49 V and 0.58 V for racemic and chiral Au films, respectively, in FIG. 16C) providing a factor of enhancement of about 20%.

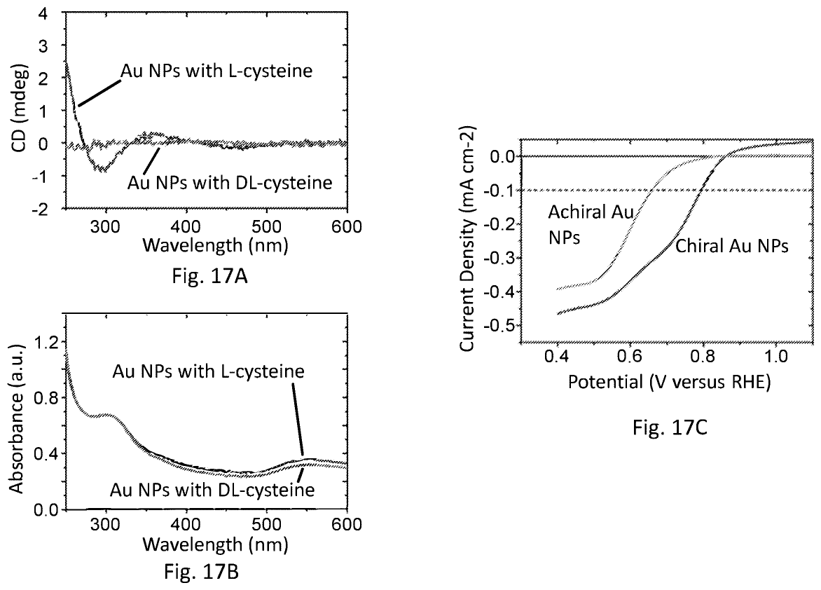

A similar enhancement due to chirality was also found in Au nanoparticles with L- or D-cysteine (FIGS. 17A to 17C). The synthesis of chiral gold nanoparticles was done by following the procedure reported in [74]. Typically, cubic Au seeds were first synthesized and dispersed in aqueous Cetrimonium bromide (CTAB) (1 mM) solution. 0.8 ml of 100 mM CTAB and 0.2 ml of 10 mM gold chloride trihydrate were added into 3.95 ml of deionized water to use as the growth solution. Cubic seed solution was then added to the growth solution, and 100 μM cysteine was added after 20 min. The sample was placed in a 30° C. bath for 2 h, and the pink solution gradually became blue with large scattering. The solution was centrifuged twice to remove unreacted reagents.

FIGS. 17A and 17B show circular dichroism spectra (FIG. 17A) and UV-visible absorption spectra (FIG. 17A) of synthesized gold nanoparticles (Au NPs) with L- or DL-cysteine. FIG. 17C shows the current vs potential measured with gold nanoparticles (Au NPs) of different chirality. Curves were recorded at room temperature, in O₂ saturated 0.1 M KOH solution at a sweep rate of 50 mV/s. Current densities were normalized in reference to the geometric area of GCE.

Considering the large spin orbit coupling of Au, the increased ORR onset potential of chiral Au NPs as compared to achiral Au NPs, seen in FIG. 17C, confirms the additional contribution of the spin polarized electrons, induced by the chiral molecules. As will be shown below, this contribution must go beyond only relaxing the spin selection rules.

To probe the effect of chirality on materials used in fuel cells, the inventors synthesized platinum nanoparticles (Pt NPs) using the L- and D-enantiomers of cysteine as ligands. Platinum nanoparticles (Pt NPs) were synthesized using chloroplatinic acid hydrate and L- or DL-cysteine as ligands with water as a reaction media. In 718 μL of E-pure water, 82 μL of 122 mM chloroplatinic acid, 200 μL of 7.5 mM L- or DL-cysteine, and 200 μL of 200 mM NaBH₄ were added.

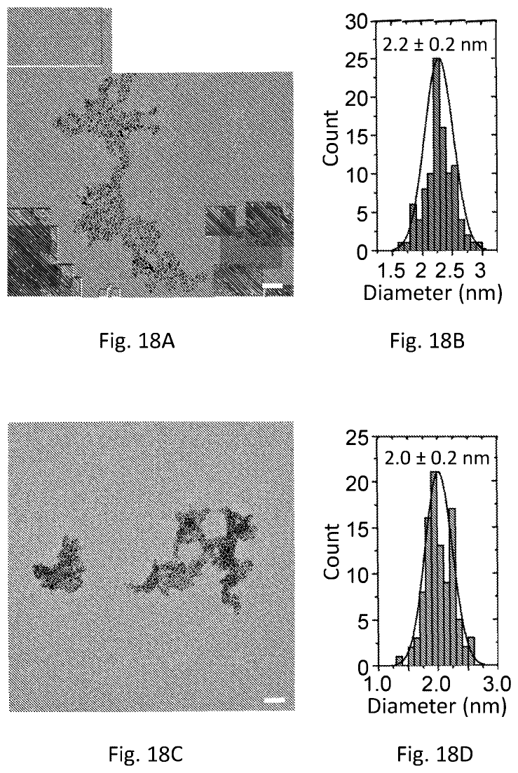

FIGS. 18A-18D show characterization of the morphology of Pt nanoparticles (NPs), in particular FIGS. 18A-18C show Transmission Electron Microscope (TEM) images and FIGS. 18B and 18D show size distributions of Pt NPs modified with the L- (FIGS. 18A, 18B) or DL-cysteine (FIGS. 18C, 18D). The scale bar in FIGS. 18A and 18C is 20 nm. TEM images were taken by using an FEI (Philips) Tecnai T12 operated at 120 kV.

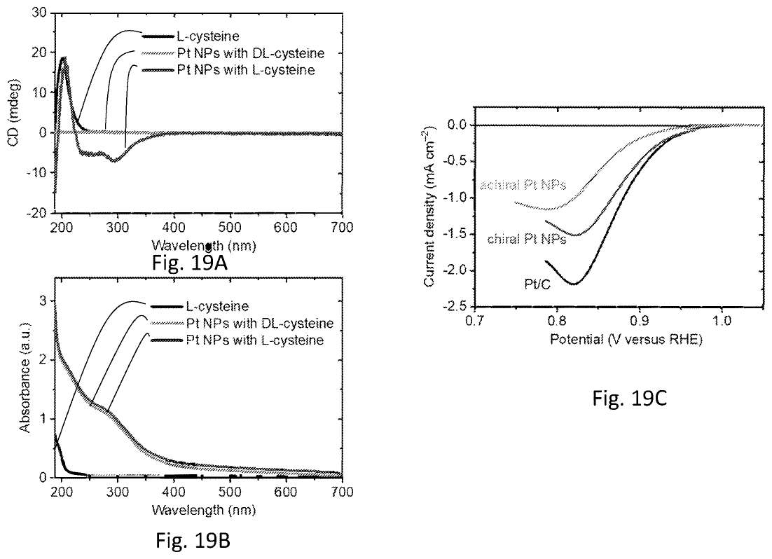

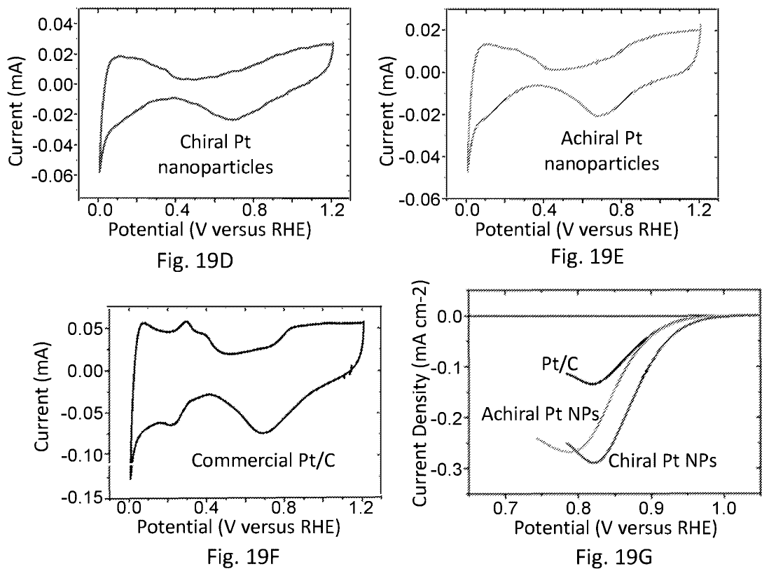

For the circular dichroism measurements, shown in FIG. 19A, the concentration of cysteine was increased to 50 mM. After two hours of magnetic stirring in N₂ atmosphere at room temperature, brownish transparent nanoparticle dispersions were obtained. The synthesized nanoparticles were analyzed after sufficient purification by rinsing NPs with E-pure water. The precipitation was done by precipitation with addition of a larger volume of isopropanol followed by centrifugation for 20 min at 10,000 rpm. FIG. 19B shows UV-visible absorption spectra of synthesized Pt nanoparticles (Pt NPs) with L- or DL-cysteine.

When a racemic mixture of L and D cysteine was used, it was referred to as achiral NPs. L-cysteine modified Pt NPs show clear CD signals in the spectral region of the absorption of the NPs, while the racemic cysteine modified NPs were CD silent (FIGS. 19A and 19B). Again, the onset potential of chiral Pt NPs far exceeds that of the achiral one (FIG. 19C). Measurements on commercial Pt/C catalyst (nominally 20% Pt on carbon black) were also conducted as the benchmark for comparison.

The electrochemically active surface area (ECSA) was measured in order to normalize the oxygen reduction currents, by using the hydrogen adsorption/desorption method on platinum in alkaline conditions [64]. 0.1 M KOH aqueous solution was first purged with O₂, and a continuous steam of argon was introduced into the cell to maintain an inert atmosphere. The CV curves were recorded between 0.0 V and 1.2 V versus the RHE with a scan rate of 50 mV/s and are shown in FIGS. 19D-19F for chiral (FIG. 19D), achiral Pt NPs (FIG. 19E), and commercial Pt/C catalyst in N₂-saturated 0.1 M KOH (FIG. 19F), respectively. The ECSA was determined by integrating the hydrogen adsorption charge on the CVs and calculated as: ECSA=Q_{des}/(m×Q_{ref}), where Q_{des} is the overall charge of the H desorption, Q_{ref} is the charge density associated with a monolayer adsorption of H₂ on platinum with unit weight and m is the loading amount of platinum on electrode.

After normalization of the oxygen reduction current by the ECSA of each catalyst, the chiral Pt NPs show a higher onset potential on the basis of equivalent Pt mass for the ORR than the state-of-the-art Pt/C catalyst as shown in FIG. 19G.

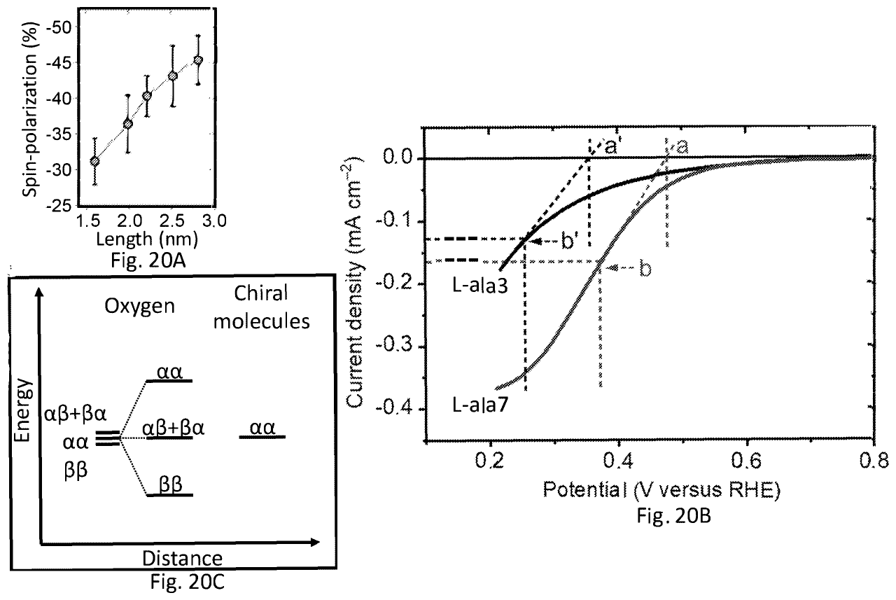

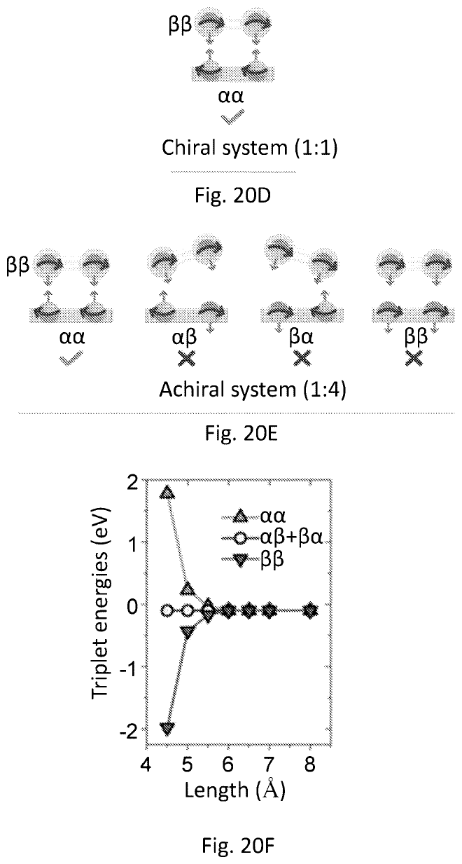

Previous studies have shown that the coupling of the electron spin direction to the molecule's chiral axis significantly exceeds the thermal energy at room temperature [65] and that the chiral molecules serve as spin filters [66]. A measure for the spin dependent filtering is provided by the spin polarization P, which is defined as

$$P = \frac{{I}_{α} - {I}_{β}}{{I}_{α} + {I}_{β}} \qquad ( 3 )$$

where I_{α} is the electron current with the electron spins pointing parallel to their velocity and I_{β} is the electron current with their spin pointing antiparallel to their velocity. The effect of chiral molecules on the ORR efficiency can be revealed by probing the correlation between the length of the chiral molecules and the spin polarization of the electrons transmitted through them. FIG. 20A shows the dependence of the spin polarization on the length of the chiral oligopeptides, adapted with permission from [67]. The conduction is higher for electrons with their spins aligned parallel to their velocity and the magnitude of the spin polarization increases from 30% to 45% as the oligopeptide length increases [67]. Based on the spin polarization results, it is possible to calculate the dependence of the current in the reduction process on the spin polarization.

The electron transfer number for the oxygen reduction process can be estimated by comparison of the spin polarization shown in FIG. 20A and the current-voltage profiles shown in FIGS. 14A-14D above (in particular, FIGS. 14C and 14D) considering the case for the ORR through L-ala3 versus the ORR through L-ala7. If the rate limiting ORR step involves transfer of a single electron, then the ratio of the spin polarizations through the two peptide films should be equal to the ratio of the observed currents through the films. If, however, there is a multiple electron process (n electrons transferred in the reaction step) then the ratio should be a multiplication of each spin effect. This logic suggests that the following equation can be used:

$$\frac{{SP}_{a l a 7} \times {I}_{a l a 7}}{{SP}_{a l a 3} \times {I}_{a l a 3}} = {( \frac{{I}_{a l a 7}}{{I}_{a l a 3}} )}^{n} \qquad ( 4 )$$

to estimate n. On the left, the product of the spin polarization for L-ala7 (SPₐₗₐ₇=45±3%) and SPₐₗₐ₃=L-ala3 (31±3%) and the current densities, Iₐₗₐ₇ and Iₐₗₐ₃, represent the spin polarized current through each film. The current densities, Iₐₗₐ₇ and Iₐₗₐ₃, are estimated in the manner illustrated by FIG. 20B. In order to obtain two current densities at the same overpotential, the inventors first took the tangent at maximum slope of the reduction current and extrapolated it to current density of zero, obtaining the intersections (a and a′). From the intersection, they then moved to the negative potential with 0.1 V (b and b′). The current density at this potential was regarded as Iₐₗₐ₇ or Iₐₗₐ₃ (the point marked with arrows); i.e., Iₐₗₐ₇=−0.16 mA/cm² and Iₐₗₐ₃=−0.13 mA/cm²). Using these values in Eq. (4), the inventors find that n=2.8. Therefore, based on the spin polarization from FIG. 20A and the above-mentioned equation, the inventors conclude that 2.9±1.5 electrons are involved in the rate determined step of the reduction process.

If it is assumed that the oxygen reduction reaction proceeds via a four-electron (4e⁻) pathway on Pt [68], the electron transfer number is about 2.35 based on the current densities of L-ala11 and Pt surface. In addition, two-electron (2e⁻) reduction of oxygen has been reported for polycrystalline Au surfaces [69,70], so that the similar current density of Au and L-ala11 indicate that a mainly two-electron process occurs in the chiral oligopeptides coated surfaces. This number is consistent with the results calculated above by the inventors from spin polarization.

Thus, the calculation implies that 2.9±1.5 electrons are involved in the rate determining step of the reduction); a similar number of electrons was obtained by the evaluation of current density between a platinum surface and a chiral monolayer (FIG. 12). This finding suggests that the oxygen reduction occurs through a two-electron mechanism when monolayer modified Au surface serves as the working electrode, as described above (Eq. (2) above).

Independent of the exact mechanism of the oxygen reduction, it requires at least two electrons in the first stage to generate either O₂²⁻ or HO₂⁻ [62]. In considering the spin statistics, it is the projection of the O₂ molecule's spin onto the chiral axis emanating from the molecular layer that is important as an O₂ molecule approaches the SAM. FIG. 20C shows the splitting in the spin states of the triplet oxygen upon interaction with the spin polarized electrons residing on the chiral molecules. For O₂, with its unpaired electrons, 1 and 2, three possible spin states, α(1)α(2), β(1)β(2), and [α(1)β(2)+β(1)α(2)]/\sqrt{2} are possible. In the case of chiral oligopeptides, the two electrons injected from the monolayer have the same spin projection on the molecular axis, namely their state will be aa. Thus, the reaction barrier is affected by an entropic factor (related to the spin statistics) and an enthalpic factor arising from the stabilization of the β(1)β(2) state of the O₂ by the spin exchange interaction with the polarized electrons on the chiral molecules.

FIGS. 20D and 20E show the possible spin states in the case of a chiral system (FIG. 20D) and in the case of an achiral one (FIG. 20E). In the case of an achiral system the two electrons can have four possible configurations from which only one of them leads to reaction. In the chiral system, there is only one possible configuration, and the electrons are strongly coupled to the molecular frame, as a result this is the only configuration that can lead to reaction.

While in the chiral molecules the spin direction is defined with respect to the molecular axis, on the oxygen the three degenerate spin states split as the molecule approaches the chiral monolayers; i.e., its spin states split, like in the case of a magnetic field, and the state β(1)β(2) will be stabilized. As the oxygen interacts (electron cloud overlaps) with the chiral monolayer film, these interactions grow in strength because of the spin-exchange effect (FIG. 20C). This effect reduces the enthalpic barrier and a more efficient injection of the spins from the monolayer into the oxygen system results. Moreover, the O₂'s spin state alignment with the chiral film reduces the entropic contributions to the free energy barrier (FIGS. 20D and 20E). For the achiral film, there are four spin states possible in the monolayer αα, ββ, αβ and βα, from which only one will enable efficient electron transfer to the oxygen (thus the reaction probability is only 1 in 4). Moreover, because the spins on the achiral monolayers are not coupled to the molecular frame, they will not split the spin states of the oxygen and the enthalpic barrier will not be reduced.

Model calculations support the mechanism described above. The theoretical simulations treat the chiral molecule as a chain of nuclear sites, each of which is carrying a single electron level and is coupled to both its nearest neighbors and next-nearest neighbors via both elastic and inelastic spin-orbit interactions [70,71].

The inelastic component in this model is composed of nuclear vibrations that couple to the electronic structure, through both spin-independent and spin-dependent electron-vibration coupling. These two components originate from nuclear motion that changes the nuclear confinement potential and, hence, pertain to both the overlap matrix elements included in the tunneling rates between nuclei as well as to the spin-orbit interaction in the structure. The theoretical simulations are performed using a model for the chiral molecule based on a chain of nuclear sites, each of which is carrying a single electron level (εₘ) and is coupled to its nearest neighbours via both elastic (t₀) and inelastic (t₁) hopping and to its next-nearest neighbours via both elastic (λ₀) and inelastic (λ₁) spin-orbit interactions, see refs. (24) and (25). The inelastic component in this model is composed of nuclear vibrations, modes ωₘ, that couple to the electronic structure, through both spin-independent (t₁) and spin-dependent (λ₁) electron-vibration coupling. These two components originate from nuclear motion that changes the nuclear confinement potential V(r) and, hence, pertain to both the overlap matrix elements included in the tunnelling rates between nuclei as well as to the spin-orbit interaction in the structure. The chiral molecule is attached on one end to a metallic reservoir

$$( {ℋ}_{r e s} = {\sum }_{k} {ϵ}_{k} {ψ}_{k}^{†} {ψ}_{k} ) ,$$

[70] and [71], whereas the opposite end is connected to the O₂ molecule by way of a direct via direct exchange interaction v of the form

$$v = 〈 {ψ}_{N}^{†} \vert σ \cdot {S}_{{O}_{2}} \vert {ψ}_{N} 〉 , where {ψ}_{N}^{†} ( {ψ}_{N} )$$

denotes the creation (annihilation) spinor at the molecular site N, whereas σ is the vector of Pauli matrices, and S_{O}_{₂}=S₁+S₂ is the spin operator for the O₂ molecule, where S_{1,2} denotes the spin ½ operator for the two unpaired electrons. The exchange integral v is calculated as function of the distance R between the chiral and O₂ molecules by using the expression for the exchange between the electrons in an H₂ molecule,

$$v = {j}_{0} \frac{𝒜 - ℬ}{5 {a}_{0}} ,$$

$$𝒜 = \frac{6}{s} ( {S}^{2} ( γ + lns ) - {S}^{′2} {E}_{1} ( 4 s ) + 2 S {S}^{′} {E}_{1} ( 2 s ) ) ,$$

$$ℬ = ( - \frac{25}{8} + \frac{23 s}{4} + 3 {s}^{2} + \frac{{s}^{3}}{3} ) {e}^{- s} , S = ( 1 + s + \frac{{s}^{2}}{3} ) {e}^{- s} ,$$

where j₀=e²/4πε₀, e is the electron charge, ε₀ is the vacuum permittivity, S′(s)=−S(s), s=R/a₀, a₀ is the Bohr radius, γ is the Euler constant, and E₁(x) is the exponential integral.

For the simulations, the inventors have modelled a chiral molecule with six turns of eight ions per turn, and the parameters (in units of t₀=40 meV) where μ is the overall chemical potential for the system, whereas Γ₀ denotes the coupling strength between the metallic reservoir and the chiral molecule. All simulations are done at T=300 K as summarized in Table 4 below:

TABLE 4

| t₁ | λ₀ | λ₁ | εₘ − μ | ωₘ | Γ₀ |
|---|---|---|---|---|---|
| 1/10 | t₀/40 | 1/100 | −2 | 1/10,000 | t₀/1,000 |

One end of the chiral molecule is attached to a metallic reservoir, and the opposite end interacts with the O₂ molecule by a direct exchange interaction v which is calculated as a function of the distance R between the chiral and O₂ molecules (see FIG. 20F described below) by using the expression for the exchange between the electrons in an H₂ molecule [70]. The exchange interaction is

$$v = < {ψ}_{N}^{†} \vert σ \cdot {S}_{{O}_{2}} \vert {ψ}_{N} > , where {ψ}_{N}^{†} ( {ψ}_{N} )$$

denotes the creation (annihilation) spinor at the molecular site N, σ is the vector of Pauli matrices, and S_{O}_{₂} is the spin operator for the O₂ molecule. The assembly of the metal, chiral molecule, and O₂ molecule constitutes an open system in which the charge distribution and accompanied spin polarization of the chiral molecule, and the magnetic moment of the O₂ molecule are determined in a self-consistent computation, using non-equilibrium green functions. FIG. 12F shows the effect of the helix's interaction on the energies of the O₂ molecule's spin substates by showing the calculated triplet energy levels on the oxygen presented as a function of distance between the chiral molecule and the oxygen.

Although a simple model, the calculations show a splitting of the triplet state sublevels that can be hundreds of meV (tens of kcal/mole). These findings are consistent with recent works that show enhanced oxygen reduction efficiency with magnetic electrodes [72, 73], presumably because of the spin alignment of the injected electrons. The proposed mechanism should be relevant for simultaneous two electron reduction as well as for a sequential process, as long as the second electron is injected on a time scale shorter than the spin depolarization time.

Given that the CISS effect can enhance the rate of multi-electron reaction steps by reducing the number of accessible spin channels, it is interesting to conjecture about its implications for the glucose oxidation process, in which six oxygen molecules and 24 electrons are involved. With the large number of multi-electron transfer steps possible in such a complex redox scheme, the reduction in the entropy of activation by spin filtering could enhance the overall rate by more than an order of magnitude for chiral biomolecules. Homochirality in biological organisms represents an entropy reduction that increases the organisms Gibbs free energy. It may be that the respiration process and its strong benefit from homochirality, because of the lower number of possible spin states (lower entropic reaction barrier), helps drive this selection. This new mechanism in which spin filtered electrons enhance the overall reaction efficiency may explain, in part, why life has preserved chirality so consistently over evolution.

The present disclosure demonstrates that controlling the spin in multi-electron transfer processes, like the ORR, results in two contributions to the reaction rates. The first is the correspondence with spin selection constraints, allowing for reactions to occur on a triplet potential energy surface. The second is in reducing the number of states available for the reactions, thereby reducing entropic barriers. The present results imply that control over the electron spin is an important attribute for catalysts that are used in important oxygen related reactions, and it reduces the overpotential and increases the current density.

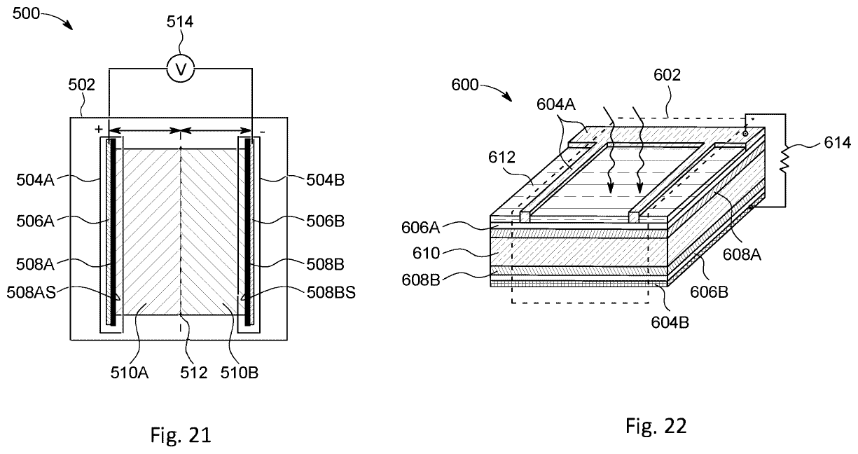

Reference is made to FIG. 21 showing a possible configuration of an energy storage device 500 comprising an electrochemical cell configured as a battery 502. The battery 502 comprises inter alia an electrode 504A and a counter-electrode 504B. Each of the electrodes 504A and 504B comprises a respective substrate 506A and 506B having an electrically conductive surface and carrying a respective chiral system 508A and 508B. The chiral system 508A and/or 508B may be at least one of organic and inorganic matter having chiral properties. As described above, the chiral-induced spin selectivity (CISS) effect enables to reduce the resistance of the electrode interface and reduce dramatically the overpotential needed for the chemical process by aligning the electrons spins. As electrons flow from one material to another in the battery cell, the spin of such electrons has an effect on the work function and the internal resistance. The reduction of the work function and the internal resistance of batteries and battery components are important aspects in the overall performance of the battery. In particular, reducing the internal resistance of such energy storage devices can lead to more efficient electrochemical reactions, reducing resistivity waste, and increasing the energy storage device performance (e.g., capacity, charging time, reduced temperatures and more). The batteries may be rechargeable batteries or disposable batteries. In this specific and non-limiting example, the electrode 504A is configured to interact with a first electrolyte 510A of the battery 502, and the counter-electrode 504B is configured to be interact with a second electrolyte 510B being in interaction with the first electrolyte. If the first and/or second electrolytes 510A and 510B are solid, the electrode 504A and the counter-electrode 504B are placed in contact with each electrolyte, respectively. If the first and/or second electrolytes 510A and 510B are liquid, the electrode 504A and the counter-electrode 504B are immersed in each electrolyte, respectively. In this case the first and second electrolytes 510A and 510B are in fluid communication one with the other. The two electrolytes may be made of the same material. However, the configuration of the battery is not limited to such configuration and the electrodes 504A and 504B may be immersed in the same electrolyte. The interaction between the chiral electrode and the electrolyte being configured for changing a spin state at an electrode-electrolyte interface so as to optimize the operation of the battery. In this specific and non-limiting example, the electrolytes 510A and 510B are separated by a permeable (e.g., porous) membrane/separator 512 that prevents them from mixing but provides chemical communication between the electrolytes 510A and 510B i.e., allows ions to diffuse through to keep electroneutrality of the battery 502.

The battery 502 further comprises an electric module 514 for applying a potential difference between the electrode 504A and the counter electrode 504B for at least one of charging and discharging the energy storage device 500.

The chiral systems 508A and 508B are configured for controlling the work function of the respective electrodes 504A and 504B. The interaction between the chiral systems and the electrodes causes charge rearrangement, spin polarization of the respective surfaces 508AS and 508BS and spin polarization of electrons being injected from or to the respective surfaces 508AS and 508BS so as to reduce the work function of the respective electrode 504A and/or 504B, the potential for starting the electrochemical process and the electrical internal resistance of the electrode.

In the non-limiting example of FIG. 21, the left electrode 504A is positive, signifying that electrons are being injected to the surface, whereas the right counter-electrode 504B is negative signifying that electrons are injected from the surface. The energy storage device 500 is configured to cause a reduction in the potential difference being applied by the electric module 514 between the electrode 504A and the counter electrode 504B for at least one of charging and discharging the energy storage device 500 due to the interaction between the chiral systems 508A and 508B and the respective electrode substrates 506A and 506B causing charge rearrangement, spin polarization of the surface, and spin polarization of electrons being injected to or from the respective surfaces 508AS and 508BS.

Reference is made to FIG. 22 showing a possible configuration of a photovoltaic cell module 600 comprising at least one photovoltaic cell 602 being configured and operable to receive light, convert energy of the received light into electrical energy and generate electrical power. The photovoltaic cell 602 comprises inter alia a pair of electrodes/current collectors, 604A and 604B, electrically coupling the photovoltaic cell 602 and being configured and operable to collect the electrical power. The photovoltaic cell 602 further comprises a top and bottom junction layer, 608A and 608B, respectively, an absorber layer 610 (made from semiconducting material) and an antireflection layer 612. The external electrical circuit 614 provides the generated electric current created by the excited electrons generated in the photovoltaic cell 602. In this specific and non-limiting example, each one of the electrodes 604A and 604B comprises a respective layer, 606A and 606B, having an electrically conductive surface at least partially carrying a chiral system. However, the configuration of the photovoltaic cell module 600 is not limited to this configuration. The coating with the chiral system may be applied either to the electrodes 604A and 604B as in the present example, or to the junction layers 608A and 608B, or to both the electrodes and the junction layers.

During typical operation of the photovoltaic cell 602, when light falls on a solar cell, electrons in the absorber layer 610 are excited from a lower energy “ground state,” in which they are bound to specific atoms in the solid, to a higher “excited state,” in which they can move through the solid. The junction-forming layers, 608A and 608B, induce a built-in electric field which gives a collective motion to the electrons that flow past the electrical contact layers 604A and 604B into external circuit 614 where they can do useful work.

Electron-hole recombination rate is one of critical factors in photovoltaic cell efficiency and presents a mechanism of loss in the active area. Another loss mechanism is generated by the over potential barriers that charges need to cross before entering the electrode/current collectors 604A and 604B. The layers 606A and 606B, being placed, respectively, in between the junction layers, 608A and 608B, and the metal electrodes/current collectors, 604A and 604B, are configured and operable to enhance the performance of the photovoltaic cell module. By reducing the electrodes over potential at the current collectors and enhancing charge separation efficiency while decreasing recombination loss.

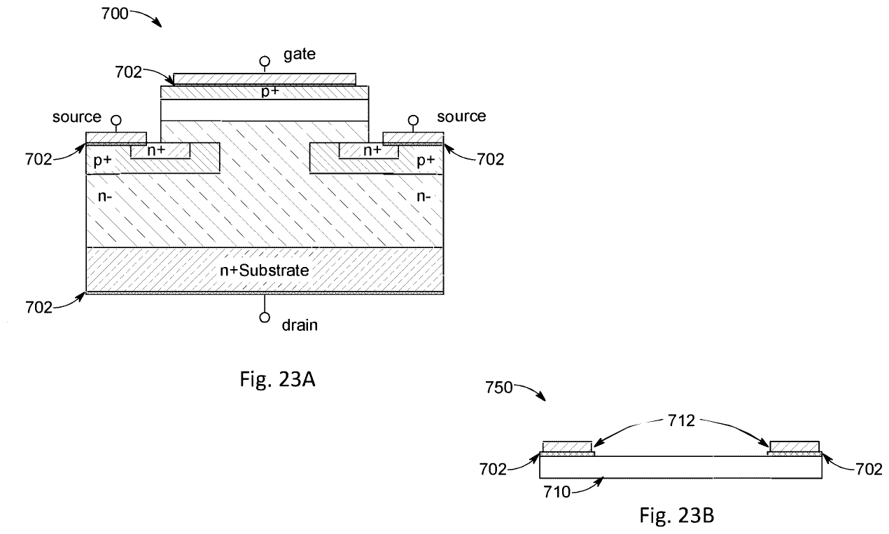

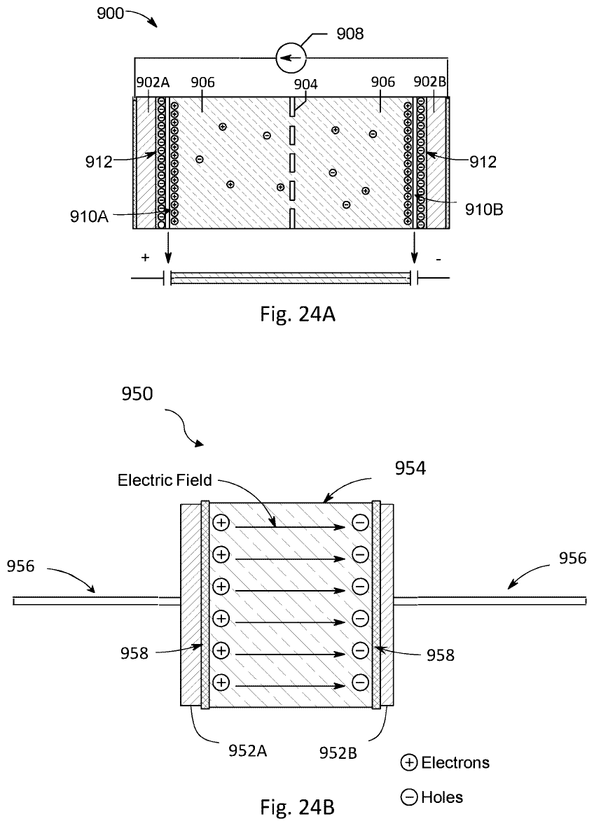

Reference is made to FIGS. 23A and 23B showing possible configurations of electrical components comprising a substrate having an electrically conductive surface at least partially carrying a chiral system. FIG. 23A shows a junction field-effect transistor (JFET) 700 in which chiral coating 702 covers the electrodes of the gate, source and drain terminals. FIG. 23B shows an interconnect 750 comprising metal, magnetic or superconductor layers 710 and two contacts/electrodes 712 in which a chiral coating 702 is lining the interface between the outer surface of the metal, magnetic or superconductor layers 710 and the contacts/electrodes 712. In both components (700 and 750), the chiral system 702 is configured for controlling a work function of the electrical component, the interaction between the chiral system 702 and the respective surfaces of electrodes causing charge rearrangement, spin polarization of the surface and spin polarization of electrons being injected from or to the electrode surface so as to reduce the work function of the electrical component, and the electrical internal resistance of the electrical component. It should be noted that the chiral coating 702 may be applied either to the electrodes of the gate, source and drain terminals as in the example of FIG. 23A, or to the semiconductor substrates being in contact with the respective electrodes, or to both the electrodes and the semiconductor substrates. Also, regarding the example of FIG. 23B, the chiral coating 702 may be applied either to the surface of the contacts/electrodes 712 or to the outer surface of layers 710 or to both, the electrodes and the layers. The JFET 700 may be configured as an electrical switch to control the flow of electricity of an energy source and the interconnect 750 may be configured to electrically couple a plurality of electrical circuits.

Reference is made to FIGS. 24A and 24B showing possible configurations of energy storage devices 900 and 950 being configured as electrochemical capacitors. The electrochemical capacitor 900 of FIG. 24A comprises two electrodes 902A and 902B separated by an ion-permeable membrane (separator) 904, an electrolyte 906 ionically connecting both electrodes, and a power supply 908. When the electrodes are polarized by an applied voltage 908, ions in the electrolyte 906 form electric double layers 910A and 910B of opposite polarity to the respective electrode's polarity. For example, positively polarized electrodes will have a layer of negative ions at the electrode/electrolyte interface along with a charge-balancing layer of positive ions adsorbing onto the negative layer. The opposite is true for the negatively polarized electrode. The double-layers 910A and 910B serve approximately as the dielectric layer in a conventional capacitor and the efficiency of charging and discharging these electric double-layers directly affects the achieved capacitance of the storage device 900.

According to some embodiments of the novel technique of the present disclosure, each one of the electrodes 902A and 902B is coated with a chiral system 912 configured to cause a reduction in the potential difference being applied between the electrodes 902A and 902B for at least one of charging and discharging the energy storage device 900 due to the interaction between the chiral system 912 and the respective electrode causing charge rearrangement, spin polarization of the electrode surface, and spin polarization of electrons being injected to or from the electrode surface. Alternatively or additionally, the ion-permeable membrane (separator) 904 may comprise a substrate having an electrically conductive surface at least partially carrying a chiral system. A chiral membrane can enhance charge separation due to the spin filtering effect [66]. Therefore to enhance charge separation, the energy storage device of the present disclosure may include chiral electrodes and/or at least one chiral membrane.

The electrochemical capacitor 950 of FIG. 24B comprises two charged conductive plates 952A and 952B, one of the plates (e.g., 952A) is positively charged and one of the plates (e.g., 952B) is negatively charged. The capacitor 950 further comprises a dielectric 954 and connecting wires 956 carrying the current created and used for charging/discharging the capacitor 950. The dielectric 954 is operable as a separator separating between the negative and positive charges of the two charged conductive plates 952A and 952B. According to some embodiments of the novel technique of the present disclosure, each one of the conductive plates 952A and 952B is coated with a chiral system 958 configured to cause a reduction in the potential difference being applied between the conductive plates 952A and 952B for at least one of charging and discharging the energy storage device 950 due to the interaction between the chiral system 958 and the respective conductive plate causing charge rearrangement, spin polarization of the respective conducting plate surface, and spin polarization of electrons being injected to or from the respective surface.

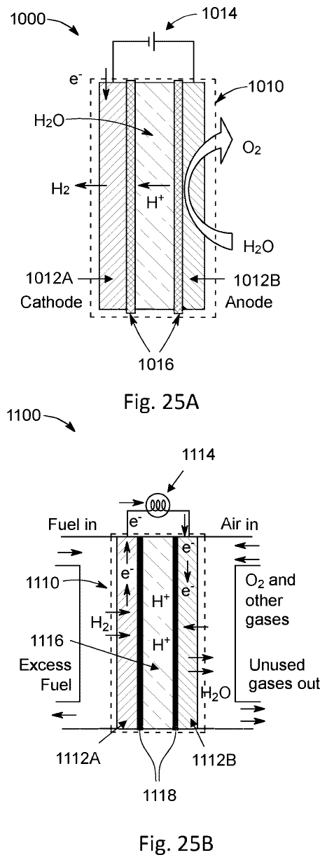

Reference is made to FIGS. 25A and 25B showing, respectively, two possible configurations of electrochemical cell systems 1000 and 1100. In this specific and non-limiting example, the electrochemical system 1000 of FIG. 25A comprises an electrochemical cell 1010 configured as a water electrolyzer in which electricity is used to split water into oxygen and hydrogen gas by electrolysis, e.g., by applying voltage through power supply 1014. However, the electrochemical cell system of the present disclosure is not limited to such configuration and another solid or liquid electrolyzer may be used instead. In this example, hydrogen gas released in this way can be used as hydrogen fuel, or remixed with oxygen to create oxyhydrogen gas, for use in welding and other applications. The electrodes, anode 1012A and cathode 1012B of the electrochemical cell 1000 are configured according to the principles of the present disclosure. Both electrodes 1012A and 1012B are carrying the chiral system 1016 as described in the present disclosure and can be immersed in the water which serves as the electrolyte in this specific and non-limiting example. The electrolyte may also be solid such that the electrodes are placed in contact with the solid electrolyte. The interaction between the chiral electrodes and the water is configured for changing a spin state at an electrode-electrolyte interface so as to optimize the operation of the electrochemical system 1010. The electrochemical system 1100 of FIG. 25B comprises an electrochemical cell configured as a fuel cell 1110 converting a chemical energy of a fuel into electricity. The fuel cell 1110 comprises inter alia two electrodes, anode 1112A and cathode 1112B, an electrolyte 1116 specifically designed so ions can pass through it, but the electrons cannot, and a load 1114 carrying the electric current created in the fuel cell 1110. The electrodes, 1112A and 1112B, of the fuel cell 1110 are configured according to the principles of the present disclosure. Both electrodes 1112A and 1112B are carrying the chiral system 1118 as described in the present disclosure. The interaction between the chiral electrodes 1112A and 1112B and the electrolyte 1116 is configured for changing a spin state at an electrode-electrolyte interface so as to optimize the operation of the electrochemical system 1100.

1. A method for controlling a work function of at least one surface comprising:
measuring a first work function of a first surface;
depositing a chiral system on the first surface to cause change in the first work function;
applying a potential difference between the first surface and a second surface, such that to create a charge transfer between the first and second surfaces;
measuring a second work function of the first surface carrying the chiral system; wherein
the second work function is lower than the first work function and
wherein the interaction between said chiral system and the first surface is configured for causing charge rearrangement, spin polarization of the surface, and spin polarization of electrons being injected from or to the first surface, thereby modifying the work function of the first surface.

2. The method of claim 1, wherein depositing the chiral system on the first surface comprises chemically bonding of the chiral system to the first surface or physically adsorbing the chiral system on the first surface.

3. The method of claim 1, wherein said chiral system comprises at least one of organic and inorganic matter having chiral properties.

4. The method of claim 3, wherein said chiral system comprises at least one of the following chiral organic materials: polypeptides, oligopeptides, amino acids, proteins DNA, helicenes, chiral polymer or any combination thereof or the following chiral inorganic material: chiral oxides, chiral metals and chiral crystals or any combination thereof.

5. The method of claim 1, wherein said chiral system is configured as a single- or multi-layer structure operating as a layer improving charge separation.

6. The method of claim 5, wherein said chiral system comprises a self-assembled monolayer of the chiral molecules, or chiral biomolecules.

7. The method of claim 1, wherein when said first surface is configured and operable as an electrode and said second surface is configured and operable as a counter electrode further comprising interacting at least one chiral coated surface with an electrolyte to be used as an electrode and another surface as counter electrode before applying the potential difference, the interaction between said chiral electrode and the electrolyte being configured for changing a spin state at an electrode-electrolyte interface.

8. An electrode for use in an electrochemical process comprising a substrate having an electrically conductive surface carrying a chiral system, wherein said chiral system is configured for controlling a work function of the electrode by application of a potential difference between said electrically conductive surface and a second surface thereby creating a charge transfer between said electrically conductive surface and the second surface, interaction between said chiral system and said electrically conductive surface causing charge rearrangement, spin polarization of the electrically conductive surface and spin polarization of electrons being injected from or to the electrically conductive surface so as to reduce the work function of the electrode, the potential for starting the electrochemical process and the electrical internal resistance of the electrode.

9. The electrode of claim 8, characterized by at least one of the following:
said chiral system comprises at least one of organic and inorganic matter having chiral properties;
said chiral system at least one of the following chiral organic materials; polypeptides, oligopeptides, amino acids, proteins DNA, helicenes, chiral polymer or any combination thereof or the following chiral inorganic material: chiral oxides, chiral metals and chiral crystals or any combination thereof;
said chiral system is configured as a single- or multi-layer structure;
said chiral system is either chemically bound to said surface or physically adsorbed on it;
said electrode is made of at least one of metal, chiral conductor and semiconductor;
said electrode is configured as a photoabsorber.

10. (canceled)

11. The electrode of claim 8, wherein said chiral system is configured as a single- or multi-layer structure, said chiral system comprising a self-assembled monolayer of the chiral molecules.

12. (canceled)

13. (canceled)

14. (canceled)

15. (canceled)

16. The electrode of claim 8, wherein said chiral system comprises at least one of the following chiral organic materials, polypeptides, oligopeptides, amino acids, proteins DNA, helicenes, chiral polymer or any combination thereof or the following chiral inorganic material, chiral oxides, chiral metals and chiral crystals or any combination thereof, said electrode being characterized by at least on of the following:
said electrode is configured as a photoabsorber;
the electrode comprises at least one layer of photoabsorber having a chiral propertie;
said chiral system comprises at least one layer of photoabsorber having chiral properties;
photoabsorbing nanoparticles bound to the electrode via said chiral system.

17. (canceled)

18. (canceled)

19. (canceled)

20. (canceled)

21. An electrochemical cell system comprising:
an electrochemical cell comprising at least a first electrolyte; and
a chiral electrode configured as the electrode having the surface with the controlled work function according to claim 8, wherein said chiral electrode carries the chiral system and is configured to interact with the first electrolyte, the interaction between said chiral electrode and the first electrolyte being configured for changing a spin state at an electrode-electrolyte interface so as to optimize an operation of the electrochemical system.

22. The electrochemical cell system of claim 21, further comprising a counter-electrode connectable to the chiral electrode and being configured to interact with a second electrolyte being in chemical communication the first electrolyte, wherein a potential energy is capable of being applied between the chiral electrode and the counter-electrode.

23. The electrochemical cell system of claim 22, wherein said counter-electrode comprises a substrate having an electrically conductive surface at least partially carrying a chiral system.

24. The electrochemical cell system of claim 23, wherein said chiral system comprises at least one of organic and inorganic matter having chiral properties.

25. The electrochemical cell system of claim 24, wherein said chiral system comprises at least one of the following chiral organic materials: polypeptides, oligopeptides, amino acids, proteins DNA, helicenes, chiral polymer or any combination thereof, or the following chiral inorganic material: chiral oxides, chiral metals and chiral crystals or any combination thereof.

26. The electrochemical cell system of claim 22, characterized by at least one of the following:
said chiral system is configured as a single- or multi-layer structure;
said chiral system is either chemically bound to said surface of the electrode or physically adsorbed on it;
said electrode is made of at least one of metal, chiral conductor and semiconductor.

27. The electrochemical cell system of claim 25, wherein said chiral system is configured as a single- or multi-layer structure, said chiral system comprising a self-assembled monolayer of the chiral molecules.

28. (canceled)

29. (canceled)

30. The electrochemical cell system of claim 22, characterized by at least one of the following:
the first and second electrolytes are made of the same material;
the electrochemical cell system further comprises a membrane being configured to create a separation between said first and second electrolytes.

31. (canceled)

32. The electrochemical cell system of claim 22, further comprising a membrane being configured to create a separation between said first and second electrolytes, wherein said membrane comprises a substrate having an electrically conductive surface at least partially carrying a chiral system.

33. The electrochemical cell system of claim 32, characterized by at least one of the following:
said chiral system comprises at least one of organic and inorganic matter having chiral properties;
said chiral system comprises at least one of the following chiral organic materials, polypeptides, oligopeptides, amino acids, proteins DNA, helicenes, chiral polymer or any combination thereof, or the following chiral inorganic material, chiral oxides, chiral metals and chiral crystals or any combination thereof,
said chiral system is configured as a single- or multi-layer structure;
said chiral system is either chemically bound to said surface of the substrate or physically adsorbed on it;
said substrate is made of at least one of metal, chiral conductor and semiconductor.

34. (canceled)

35. The electrochemical cell system of claim 32, wherein said chiral system is configured as a single- or multi-layer structure, said chiral system comprising a self-assembled monolayer of the chiral molecules.

36. (canceled)

37. (canceled)

38. (canceled)

39. The electrochemical cell system of claim 21, being configured to be immersed in a solution containing oxygen and being operable to enhance electron transfer from the electrodes to oxygen and to lower an overpotential of an oxygen reduction reaction.

40. An energy storage device comprising:
at least one electrochemical cell of claim 21,
an electric module for applying a potential difference between said electrode and a counter-electrode connectable to said electrode for at least one of charging and discharging the energy storage device,
wherein the energy storage device is configured to cause a reduction in the potential difference being applied between the electrode and the counter electrode for at least one of charging and discharging the energy storage device due to the interaction between said chiral system and said electrode causing charge rearrangement, spin polarization of the surface, and spin polarization of electrons being injected to or from the surface.

41. The energy storage device of claim 22, characterized by one of the following:
at least one of the first and second electrolyte comprises active materials being a chiral material;
the energy storge device is configured as an electrical battery;
the energy storage device is configured as an electrochemical capacitor.

42. (canceled)

43. (canceled)

44. A photovoltaic cell module comprising:
at least one photovoltaic cell being configured and operable to receive light, convert energy of the received light into electrical energy and generate electrical power;
at least a pair of electrodes electrically coupling the photovoltaic cell and being configured and operable to collect the electrical power; and
a layer having an electrically conductive surface at least partially carrying a chiral system, said layer being placed in between the at least one photovoltaic cell and the at least a pair of electrodes and being configured and operable to enhance the performance of the photovoltaic cell module,
wherein at least one of electrodes of said pair of electrodes is configured as the electrode of claim 8.

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. (canceled)

57. (canceled)

58. (canceled)

59. (canceled)

60. (canceled)
